(19) United States
(12) Patent Application Publication
(10) Pub. No.: US 2013/0269775 A1
(43) Pub. Date: Oct. 17, 2013

(54) POLYESTER FILM, METHOD FOR PRODUCING THE SAME, BACK SHEET FOR SOLAR CELL, AND SOLAR CELL MODULE

(71) Applicant: FUJIFILM Corporation, Tokyo (JP)

(72) Inventors: Kiyokazu HASHIMOTO, Kanagawa (JP); Zemin SHI, Kanagawa (JP); Maki MIFUNE, Kanagawa (JP)

(21) Appl. No.: 13/911,707

(22) Filed: Jun. 6, 2013

Related U.S. Application Data
(63) Continuation of application No. PCT/JP2011/077717, filed on Nov. 30, 2011.

(30) Foreign Application Priority Data
Dec. 8, 2010 (JP) 2010-274008

(51) Int. Cl. H01L 31/048; B29C 47/00

(52) U.S. Cl. CPC H01L 31/0487; B29C 47/0057
USPC 136/256; 428/220; 264/210.1; 264/476

(57) ABSTRACT

A method for producing a polyester film includes: an unstretched film formation step of forming an unstretched polyester film having a thickness of from 2.5 mm to 5.0 mm by melt-extruding a polyester resin using an extruder, and cooling the polyester resin; and a stretching step of stretching the formed unstretched polyester film in at least one direction after heating the formed unstretched polyester film so as to have a mean temperature T1 (° C.), a surface temperature, and a central temperature. The mean temperature T1 (° C.) satisfies a relationship represented by formula (1): Tg−20° C.<T1<Tg+25° C., wherein Tg represents a glass transition temperature (° C.) of the unstretched polyester film. The surface temperature is higher than the central temperature by from 0.3° C. to less than 15° C.

### CROSS-REFERENCE TO RELATED APPLICATIONS

This application is a continuation application of International Application No. PCT/JP/2011/077717, filed Nov. 30, 2011, the disclosure of which is incorporated herein by reference in its entirety. Further, this application claims priority from Japanese Patent Application No. 2010-274008, filed Dec. 8, 2010, the disclosure of which is incorporated herein by reference in its entirety.

### TECHNICAL FIELD

The present invention relates to a method for producing a polyester film, a polyester film obtained by the method, a back sheet for a solar cell, and a solar cell module.

### BACKGROUND ART

In recent years, solar power generation converting sunlight into electricity has received wide attention from the viewpoint of protection of global environment. A solar cell module used for solar power generation has a structure of (sealant)/solar cell device/sealant/back sheet layered in this order on glass on which sunlight is incident.

The solar cell module is required to have a high weather resistance performance of securing cell functions such as power generation efficiency over a long period of decades even in a severe use environment where the module is exposed to wind and rain or direct sunlight. In order to impart such weather resistance performance, respective materials included in the solar cell module, such as a back sheet and a sealing material that seals the devices, are also required to have weather resistance.

For the back sheet included in the solar cell module, generally a resinous material such as polyester resin is used. A polyester film tends to degrade with time because there are generally many carboxy groups or hydroxy groups on the polyester film surface, easily causing hydrolysis in an environment where water exists. For this reason, a polyester film that is used for the solar cell module installed in such an environment as outdoors where it is exposed constantly to wind and rain is required to have a suppressed hydrolysis property. In addition, a polyester film that is used for a solar cell module is also required to have voltage resistance.

As a film for sealing the back side of a solar cell in which a polyester film is used, a film for sealing the back side of a solar cell in which a thermal adhesive layer is layered on a polyester film is disclosed (for example, see JP 2003-60218 A). In addition, JP 2007-204538 A discloses a polyester film for sealing the back side of a solar cell in which the contents of titanium compounds derived from catalysts and phosphorus compounds are within pre-determined ranges and the concentration of terminal carboxy groups is 40 eq/ton or less.

For production of a thermoplastic resin film, a method including forming an unstretched film from a molten thermoplastic resin material and stretching it has been conventionally used. JP 2009-233918 A discloses, as a method for producing a thermoplastic resin film having few defects in terms of wrinkles at the end, scratches, transverse thickness-difference lines, and the like, which occur during production of a thermoplastic resin film, a production method in which the temperature of a pre-heating roll is set at a temperature which is equal to or lower than the glass transition temperature of a thermoplastic resin constituting the thermoplastic resin sheet and in which the thermoplastic resin sheet is heated and stretched using a radiant heating source surrounded by insulating materials.

### SUMMARY OF INVENTION

### Technical Problem

As described above, physical properties that are required for a polyester film used for a back sheet for a solar cell include hydrolysis resistance and voltage resistance.

The voltage resistance can be enhanced by increasing the thickness of a polyester film. However, since a polyester film having a large thickness has high rigidity, the force pressing the film on a stretching roll during stretching for producing a film is increased, and as a result, scratches may be easily formed on a surface of the film. The scratches formed on a surface of a polyester film impair the film surface smoothness and also become a reason for impairing the voltage resistance.

JP 2009-233918 A discloses a technique for inhibiting wrinkles at the end and scratches which occur during production of a thermoplastic resin film. However, when the technique disclosed in the document is applied to production of a thick polyester film (for example, 2500 μm or more), an occurrence of scratches cannot be inhibited, and the film surface smoothness is impaired. Further, as a way of reducing an occurrence of scratches on a polyester film surface during stretching, increasing the temperature of an unstretched film may be considered. However, increasing simply the temperature of an unstretched film lowers the orientation of the film and the hydrolysis resistance of the film.

As described above, a method capable of producing a thick polyester film having both hydrolysis resistance and voltage resistance is not available yet.

The present invention is made in view of the above circumstances, and an object of the invention is to provide a method for producing a polyester film in which, even in a case of producing a polyester film with a large thickness, a polyester film having excellent film surface smoothness, excellent hydrolysis resistance, and excellent voltage resistance can be obtained.

Another object of the invention is to provide a polyester film which has excellent hydrolysis resistance and excellent voltage resistance and thus is suitable for use under a severe environment, such as use for a solar cell or the like, for a long period of time, and a back sheet for a solar cell and a solar cell module using the polyester film.

### Solution to Problem

Specific means for solving the above problems are as follows.

<1> A method for producing a polyester film, the method comprising:

an unstretched film formation step of forming an unstretched polyester film having a thickness of from 2.5 mm to 5.0 mm by melt-extruding a polyester resin using an extruder, and cooling the polyester resin; and

a stretching step of stretching the formed unstretched polyester film in at least one direction after heating the formed unstretched polyester film so as to have a mean temperature T1 (° C.), a surface temperature, and a central temperature, wherein the mean temperature T1 (° C.) satisfies a relationship represented by the following formula (1), and the surface temperature is higher than the central temperature by from 0.3° C. to less than 15° C.

Tg−20° C.<T1<Tg+25° C. formula (1)

wherein in the formula (1), Tg represents a glass transition temperature (° C.) of the unstretched polyester film.
<2> The method for producing a polyester film according to <1>, wherein the stretching step is performed by, after heating the unstretched polyester film using a pre-heating roll, stretching the unstretched polyester film with a stretching roll while heating the film with a near infrared heater or a far infrared heater, and each of a surface temperature and a surrounding atmospheric temperature of the pre-heating roll is a temperature T2 (° C.) which satisfies a relationship represented by the following formula (2)

Tg−25° C.<T2<Tg+40° C. formula (2)

wherein in the formula (2), Tg represents the glass transition temperature (° C.) of the unstretched polyester film.

<3> The method for producing a polyester film according to <1> or <2>, wherein an intrinsic viscosity of the polyester resin is in a range of from 0.6 dl/g to 0.9 dl/g.
<4> The method for producing a polyester film according to any of <1> to <3>, wherein the polyester resin has a terminal COOH amount of from 5 eq/t to 25 eq/t.
<5> The method for producing a polyester film according to any of <1> to <4>, wherein the unstretched polyester film is stretched in a transfer direction in the stretching step.
<6> A polyester film obtained by the method for producing a polyester film according to any of <1> to <5>.
<7> A back sheet for a solar cell, comprising the polyester film according to <6>.
9> A solar cell module comprising the polyester film according to <6>.

### Advantageous Effects of Invention

According to the invention, there may be provided a method for producing a polyester film in which, even in a case of producing a polyester film with a large thickness, a polyester film having excellent film surface smoothness, excellent hydrolysis resistance, and excellent voltage resistance can be obtained.

Further, according to the invention, there may be provided a polyester film which has excellent hydrolysis resistance and excellent voltage resistance and thus is suitable for use under a severe environment, such as use for a solar cell or the like, for a long period of time, and a back sheet for a solar cell and a solar cell module using the polyester film.

### BRIEF DESCRIPTION OF DRAWINGS

FIG. 1 is a schematic cross-sectional view illustrating a constitution example of a solar cell module.

### DESCRIPTION OF EMBODIMENTS

Hereinafter, the invention will be described in more detail.

[Polyester Film and Method for Producing Polyester Film]

The method for producing a polyester film according to the invention (herein below, also referred to as “a production method of the invention”) comprises:

an unstretched film formation step of forming an unstretched polyester film having a thickness of from 2.5 mm to 5.0 mm by melt-extruding a polyester resin using an extruder, and cooling the polyester resin; and

a stretching step of stretching the formed unstretched polyester film in at least one direction after heating the formed unstretched polyester film so as to have a mean temperature T1 (° C.), a surface temperature, and a central temperature, wherein the mean temperature T1 (° C.) satisfies a relationship represented by the following formula (1), and the surface temperature is higher than the central temperature by from 0.3° C. to less than 15° C.

Tg−20° C.<T1<Tg+25° C. formula (1)

wherein in the formula (1), Tg represents a glass transition temperature (° C.) of the unstretched polyester film.

By having the above steps, the production method of the invention may produce a polyester film having excellent film surface smoothness, excellent hydrolysis resistance, and excellent voltage resistance even when producing a polyester film having a large thickness.

As used herein, the description “excellent film surface smoothness” means that an occurrence of scratches such as cracks and protrusions caused by adhesion to a stretching roll or the like is suppressed on a polyester film surface.

Hereinafter, each step included in the production method of the invention will be described in order.

(1) Unstretched Film Formation Step

In the unstretched film formation step, a polyester resin is melt-extruded using an extruder followed by cooling to form an unstretched polyester film having a thickness of from 2.5 mm to 5.0 mm

When melting a polyester resin in the unstretched film formation step, for example, the polyester resin explained below may be used as a raw material resin and the resin may be dried so that the residual moisture in the polyester resin is 100 ppm or lower followed by melting using an extruder. The melting temperature is preferably from 250° C. to 320° C., more preferably from 260° C. to 310° C., and still more preferably from 270° C. to 300° C. The extruder may be a single-screw extruder or a multi-screw extruder. From the viewpoint of preventing the generation of terminal COOH through thermal decomposition, preferably, the extruder is purged with nitrogen.

Further, the polyester resin used in the production method of the invention will be explained in detail below.

The melt of the polyester resin is extruded on a chill roll (a cooling cast drum) from an extrusion die through a gear pump, a filter, and the like. In this regard, the melt may be extruded as a single layer or as multiple layers.

The melt extruded from an extruder has a thickness of from 2.5 mm to 5.0 mm, preferably from 2.8 mm to 4.5 mm, and more preferably from 3 mm to 4 mm.

Due to the melt thickness of 2.5 mm or more, a polyester film having a large thickness (for example, 200 μm or more) can be obtained even when a high stretch ratio is used during the stretching step, and thus the voltage resistance can be improved. When the thickness is less than 2.5 mm, a sufficient improvement of the voltage resistance in the polyester film cannot be obtained.

Due to the melt thickness of 5.0 mm or less, an occurrence of scratches during the stretching step is suppressed. On the other hand, when the thickness is larger than 5.0 mm, rigidity inside the film is increased so that an occurrence of scratches cannot be fully suppressed.

Further, due to the melt thickness of 2.5 mm or more, OH groups and COOH groups in the polyester are diffused inside the polyester during the period from extrusion to cooling, so that exposure of OH groups and COOH groups (which can cause hydrolysis) on the surface of the polyester film is suppressed.

When the melt is extruded from an extruder, it is preferable that the shear rate during extrusion be controlled to fall within a desired range. The shear rate during extrusion is preferably from 1 s⁻¹ to 300 s⁻¹, more preferably from 10 s⁻¹ to 200 s⁻¹, and still more preferably from 30 s⁻¹ to 150 s⁻¹. As a result of that, there occurs die swelling (a phenomenon of swelling of the melt in the thickness direction thereof) when extruded from the die. That is, since stress is generated in the thickness direction (film normal line direction), the molecular movement in the thickness direction of the melt is promoted.

Due to the influence of the die swelling caused by the extrusion of the melt at such a high shear rate, the melt contacts the die lip and a die line is likely to be generated. Therefore, it is effective to give a fluctuation (pulsation) of preferably from 0.1% to 5%, more preferably from 0.3% to 4%, and still more preferably from 0.5% to 3% to the extrusion amount of the melt.

The die swelling amount also varies in accordance with the fluctuation. In other words, since the contact time of the melt with the extrusion die can be suppressed, a continuous die line is not generated. When the fluctuation is in the range above, an increase in deformation resulting from thickness unevenness is suppressed. Such a discontinuous die line can be eliminated by the viscous effect of the melt and does not actually cause any problem. Furthermore, such a die swelling fluctuation also has an effect of fluctuating the stress in the thickness direction to thereby prompt the movement of COOH or OH.

Such a fluctuation of the extrusion amount may be achieved by fluctuating the number of rotation of a screw of an extruder or fluctuating the number of rotation of a gear pump, which is provided between the extruder and the die.

The melt extruded from an extruder is cooled by a chill roll (a cooling cast drum) and an auxiliary cooling device which is installed to face the cooling cast drum. The cooling rate is preferably from 100° C./min to 800° C./min When cold air is supplied to the side opposite from a chill roll or a cooling roll is brought into contact with the melt, cooling is promoted, and thus cooling of a thick melt film (specifically, a film having a thickness of 2.0 mm or more before stretching and a thickness of 100 μm or more or 255 μm or more after stretching) can be effectively performed to enable rapid cooling with the above described cooling rate.

The cooling rate can be obtained by forced cooling using a cooling cast drum and an auxiliary cooling device (a device that blows cold air to the melt) which is installed to face the cooling cast drum. Examples of the auxiliary cooling device that can be used include an auxiliary cooling device described in JP 7-266406 A, JP 9-204004 A, JP 2006-281531A, or the like. Further, an auxiliary cooling device such as a water mist spray type, a spray type or a water tank can be also used.

The temperature of the chill roll during cooling is preferably from −10° C. to 30° C., more preferably from −5° C. to 25° C., and still more preferably from 0° C. to 15° C. In addition, from the viewpoint of enhancing cooling efficiency by increasing adhesiveness between the melt and the chill roll, it is preferable that static electricity be applied before the melt contact the chill roll. By having a coolant pass through the inside of a cast drum, the surface temperature can be controlled to a pre-determined temperature.

In the film formation of a thick film, a reduction in the cooling rate on a cooling cast drum often causes the formation of spherulites, resulting in stretching unevenness. However, the stretching unevenness can be removed by imparting, to the cooling cast drum, temperature unevenness of from 0.1° C. to 5° C., more preferably from 0.3° C. to 4° C., and still more preferably from 0.5° C. to 3° C.

Here, the temperature unevenness refers to a difference between the highest temperature and the lowest temperature obtained by measuring the temperature of the cooling cast drum along the drum width direction.

When there is a temperature difference as described above, a temperature difference arises in the melt on the cooling cast drum, and expansion/shrinkage stress acts in the melt. When the melt contacts the cooling cast drum, an air layer is involved, and then temperature unevenness is generated. However, when the temperature unevenness in the range above is given, the melt shrinks/expands to eliminate the air layer, and thus adhesion is prompted and cooling is prompted. In contrast, when temperature unevenness exceeding the range above is given, shrinkage unevenness resulting from cooling temperature unevenness during casting arises and deformation is generated in the cast film. Thus, such temperature unevenness is not preferable.

The above temperature distribution (temperature unevenness) on the cooling cast drum can be achieved by providing a baffle plate in the drum, passing a heat medium through the inside thereof, and disturbing the flow path.

The humidity in a period (air gap) after extruding the melt from the extrusion die and before bringing the melt into contact with a cooling cast drum is preferably adjusted to be from 5% RH to 60% RH, more preferably from 10% RH to 55% RH, and still more preferably from 15% RH to 50% RH.

By adjusting the humidity in the air gap to the range above, the surface carboxylic acid amount and the surface OH amount can be adjusted.

That is, by adjusting the hydrophobicity of the air as described above, burying of the COOH groups and the OH groups from the film surface can be controlled.

In this case, the surface OH amount and the surface carboxylic acid amount are increased by adjusting the humidity to be high, and the surface OH amount and the surface carboxylic acid amount are decreased by adjusting the humidity to be low.

The effects of the air gap particularly affect the surface COOH amount. This is because the polarity of the COOH group is stronger than that of the OH group and is easily affected by the humidity of the air gap.

In the extrusion at such a low humidity, the adhesion to the cooling cast drum decreases and cooling unevenness is likely to be generated. However, by imparting a temperature distribution of from 0.1° C. to 5° C. to the cast roll, the cooling unevenness can be reduced as described above.

The unstretched polyester film having a thickness of from 2.5 mm to 5.0 mm obtained as described above is subjected to stretching in a stretching step described below.

(2) Stretching Step

In the stretching step, an unstretched polyester film that is obtained by the unstretched film formation step is stretched in at least one direction after being heated such that the mean temperature T1 (° C.) thereof satisfies the relationship represented by the following formula (1) and the surface temperature thereof is higher than the central temperature thereof by from 0.3° C. to less than 15° C.

Tg−20° C.<T1<Tg+25° C. formula (1)

In the formula (1), Tg represents the glass transition temperature (° C.) of the unstretched polyester film.

The stretching step preferably is a step in which an unstretched polyester film is heated with a pre-heating roll and then stretched by a stretching roll while being heated with a near IR heater or a far IR heater.

The unstretched polyester film subjected to stretching is heated such that the mean temperature T1 (° C.) thereof satisfies the relationship represented by the above formula (1) and the surface temperature thereof is higher than the central temperature thereof by from 0.3° C. to less than 15° C. By using an unstretched polyester film having a thickness of from 2.5 mm to 5.0 mm and controlling the film temperatures in specific ranges, the region near the film surface can be softened to the extent that occurrence of scratches is suppressed during stretching while orientation can be maintained inside the film. Thus, because a thick unstretched polyester film having a thickness of from 2.5 mm to 5.0 mm can be stretched while occurrence of scratches is suppressed without lowering the orientation of the film, the stretched polyester film obtained by the production method of the invention has both excellent hydrolysis resistance and excellent voltage resistance while maintaining the smoothness on the film surface.

Meanwhile, when the unstretched polyester film does not satisfy at least one of the relationship represented by the above formula (1) or the relationship between the surface temperature and the central temperature, scratches or protrusions caused by adhesion onto the stretching roll or the like occurs on a film surface to impair the smoothness of a film surface, or the orientation lowers, and as a result, the stretched polyester film is unable to have hydrolysis resistance or voltage resistance.

The mean temperature T1 (° C.) of the unstretched polyester film is a mean value of the surface temperature and the central temperature of the heated unstretched polyester film.

The details of the method for measuring the temperatures in the invention are as described below.

The surface temperature of a film is measured by attaching a thermocouple on two surfaces of a film to be measured. The central temperature of a film is measured by embedding a thermocouple in the central portion in the film thickness direction of the film to be measured.

The measurement range of each of the surface temperature and the central temperature of the film is from the measurement start point, which is 3 m behind (in length in the film transfer direction) the stretch start point, to the stretch start point. As described herein, the expression “stretch start point” means a point at which a transferred unstretched polyester film comes into contact with a stretching roll.

The measurement is performed by measuring both the surface temperature and the central temperature of the film at the measurement start point and every 100 msec after starting the measurement.

The mean temperature T1 (° C.) is obtained by calculating a mean value of the measured surface temperature and central temperature in each of the measurement points, and then calculating an arithmetic average of the mean values.

The difference between the surface temperature and the central temperature of the film is obtained by calculating a value by subtracting the measured central temperature from the measured surface temperature for each of the measurement points, and then calculating an arithmetic average of the values.

Examples of a method for controlling the temperatures of an unstretched polyester film such that the mean temperature T1 (° C.) thereof satisfies the relationship represented by the above formula (1) and the surface temperature thereof is higher than the central temperature thereof by from 0.3° C. to less than 15° C. includes an embodiment in which a temperature of a pre-heating roll is controlled, an embodiment in which a temperature of a pre-heating roll and a surrounding temperature of the pre-heating roll are controlled, and an embodiment in which a roll to roll distance and a film transferring rate are controlled.

It is more preferable that the mean temperature T1 (° C.) of an unstretched polyester film satisfy the relationship represented by the following formula (1-2).

Tg−10° C.<T1<Tg+20° C. formula (1-2)

In the formula (2), Tg represents the glass transition temperature (° C.) of the unstretched polyester film.

It is more preferable that the relationship between the surface temperature and the central temperature of an unstretched polyester film heated by a pre-heating roll be such that the surface temperature thereof is higher than the central temperature thereof by from 1° C. to 10° C.

In the stretching step, each of the surface temperature and the surrounding atmospheric temperature of the pre-heating roll used for heating the unstretched polyester film is preferably a temperature T2 (° C.) which satisfies the relationship represented by the following formula (2).

Tg−25° C.<T2<Tg+40° C. formula (2)

In the formula (2), Tg represents the glass transition temperature (° C.) of the unstretched polyester film.

In addition, it is preferable that in a case in which two or more pre-heating rolls are installed, the surface temperature and the surrounding atmospheric temperature of all of the pre-heating rolls satisfy the relationship represented by the above formula (2).

When both the surface temperature and the surrounding atmospheric temperature of the pre-heating roll are a temperature T2 (° C.) which satisfies the relationship represented by the above formula (2), an occurrence of scratches can be more effectively suppressed during stretching.

The surface temperature of a pre-heating roll can be measured by using a radiation thermometer (product number: RT60, manufactured by Chino Corporation).

The surrounding atmospheric temperature of a pre-heating roll is a measurement value obtained by using a thermocouple and measuring a temperature (° C.) of a surrounding space of the pre-heating roll surface in a position not affected by heat radiation from the pre-heating roll.

As a method for controlling the surrounding atmospheric temperature of the pre-heating roll to satisfy the formula (2) above, blowing hot air, heating using an IR heater, and casing using a heat insulating material around the pre-heating roll can be mentioned.

The unstretched polyester film heated by the pre-heating roll is stretched in at least one direction by a stretching roll. The stretching method may be monoaxial stretching or biaxial stretching.

One preferred embodiment of the stretching method in the invention is a stretching method which includes pre-heating an unstretched polyester film with a pre-heating roll under a condition in which the atmospheric temperature of the pre-heating roll is controlled, performing longitudinal monoaxial stretching in the transfer direction, from a position at which heating is started with a near IR heater, with a stretching roll adjusted to have a pre-determined speed ratio, and performing transverse stretching using a tenter.

Biaxial stretching may also be performed in the invention.

In biaxial stretching, for example, longitudinal stretching of a polyester sheet is performed such that the stretching stress is from 5 MPa to 15 MPa and the stretch ratio is from 2.5 times to 4.5 times in the length direction of the polyester sheet, and transverse stretching is performed such that the stretch ratio is from 2.5 times to 5 times in the width direction.

More specifically, the polyester sheet is introduced into a roll group heated to a temperature of from 70° C. to 120° C., and then longitudinally stretched in the length direction (the longitudinal direction, that is, the film proceeding direction) with a stretching stress of from 5 MPa to 15 MPa and a stretch ratio of from 2.5 times to 4.5 times, and more preferably with a stretching stress of from 8 MPa to 14 MPa and a stretch ratio of from 3.0 times to 4.0 times. After the longitudinal stretching, it is preferable to perform cooling with a roll group having a temperature of from 20° C. to 50° C.

Subsequently, it is preferable that the polyester sheet is introduced to a tenter while both ends of the sheet are held by clips, and in an atmosphere heated to a temperature of from 80° C. to 180° C., a transverse stretching is performed in a direction perpendicular to the length direction, that is, in the width direction, with a stretching stress of from 8 MPa to 20 MPa and a stretch ratio of from 3.4 times to 4.5 times, and more preferably with a stretching stress of from 10 MPa to 18 MPa and a stretch ratio of from 3.6 times to 5 times.

A stretched area ratio (longitudinal stretch ratio×transverse stretch ratio) by the biaxial stretching is preferably from 9 times to 20 times. If the area ratio is from 9 times to 20 times, it is possible to obtain a biaxially oriented polyester film having a thickness after stretching of from 250 μm to 500 μm, a high degree of plane orientation, a degree of crystallinity of from 30% to 40%, and an equilibrium moisture content of from 0.1% by mass to 0.25% by mass.

The method of biaxial stretching may be either a sequential biaxial stretching method that performs stretching in the length direction and in the width direction separately as described above, or a simultaneous biaxial stretching method that performs stretching in the length direction and in the width direction at the same time.

(3) Thermal Fixation Step

In order to provide planarity and dimension stability by completing the crystal orientation of the obtained biaxially stretched film, it is preferable to subsequently perform a thermal fixation treatment in the tenter. It is preferable to perform a thermal fixation treatment on the biaxially stretched film with a tension of from 1 kg/m to 10 kg/m and a temperature of from 170° C. to 230° C. It is possible to improve planarity and dimension stability and control the difference between moisture contents measured arbitrarily at 10 cm intervals to be from 0.01% by mass to 0.06% by mass by performing a thermal fixation treatment under such a condition.

Preferably, a thermal fixation treatment is performed at a temperature of from the glass transition temperature (Tg) of the unstretched polyester film to less than the melting point (Tm) thereof for from 1 second to 30 seconds, and then the film is uniformly cooled, and further cooled down to room temperature. Generally, if a thermal fixation treatment temperature (Ts) is low, thermal contraction of a film is large, and therefore a high thermal treatment temperature is preferable to provide a high thermal dimension stability. However, if a thermal treatment temperature is too high, oriented crystallinity decreases, and as a result, there are cases in which the moisture content of the formed film increases and hydrolysis resistance deteriorates. Therefore, the thermal fixation treatment temperature (Ts) of the polyester film according to the present invention is preferably 40° C.≦(Tm−Ts)≦90°) C., and more preferably 50° C.≦(Tm−Ts)≦80° C., and still more preferably 55° C.≦(Tm−Ts)≦75° C.

The obtained polyester film can be used as a back sheet for constituting a solar cell module; however, since there are cases in which an atmosphere temperature increases to about 100° C. when using the module, the thermal fixation treatment temperature (Ts) is preferably from 160° C. to Tm-40° C. (under a condition of Tm-40° C.>160° C.), and more preferably from 170° C. to Tm-50° C. (under a condition of Tm-50° C.>170° C.), and still more preferably from 180° C. to Tm-55° C. (under a condition of Tm-55° C.>180° C.). The thermal fixation treatment is preferably carried out in two or more divided areas by sequentially lowering the temperature with a temperature difference in a range of from 1° C. to 100° C.

Optionally, a 1 to 12% relaxation treatment may be performed in the width direction or the length direction.

The thermally fixed polyester film is usually cooled down to Tg or lower, cut at both ends of the polyester film held by clips, and rolled into a roll shape. At this time, it is preferable to perform a 1 to 12% relaxation treatment in the width direction and/or the length direction in a temperature range of from Tg to the final thermal fixation treatment temperature.

From the viewpoints of dimension stability, it is preferable to perform cooling, from the final thermal fixation treatment temperature to room temperature, at a cooling rate of from 1° C./sec to 100° C./sec. Particularly, it is preferable to perform cooling from Tg+50° C. to Tg at a cooling rate of from 1° C./sec to 100° C./sec. The methods for cooling and relaxation are not particularly limited, and conventionally known methods can be used, but from the viewpoints of improvement in the dimension stability of the polyester film, it is particularly preferable to perform these treatments while sequentially cooling the film in multiple temperature ranges.

When producing the polyester film, for the purpose of improving the strength of the polyester film, known stretching used for stretched films, such as multi-step longitudinal stretching, re-longitudinal stretching, re-longitudinal and transverse stretching, and transverse-longitudinal stretching, may be performed. The order of a longitudinal stretching and a transverse stretching may be switched.

(Polyester Resin)

The polyester resin used for the production method of the invention is described in detail herein below.

The polyester resin used for the production method of the invention may be synthesized through a step of obtaining a polycondensation product by a polycondensation reaction of an esterification reaction product that is obtained by an esterification reaction of (A) a dicarboxylic acid component and (B) a diol component.

Further, commercially available products may be also used as a polyester resin.

—Esterification Reaction—

Examples of (A) the dicarboxylic acid component that is used as a raw material of the polyester resin include dicarboxylic acids such as aliphatic dicarboxylic acids including malonic acid, succinic acid, glutaric acid, adipic acid, suberic acid, sebacic acid, dodecanedioic acid, dimer acid, eicosanedioic acid, pimelic acid, azelaic acid, methylmalonic acid, and ethylmalonic acid, alicyclic dicarboxylic acids including adamantane dicarboxylic acid, norbornene dicarboxylic acid, isosorbide, cyclohexane dicarboxylic acid, and decalin dicarboxylic acid, and aromatic dicarboxylic acids including terephthalic acid, isophthalic acid, phthalic acid, 1,4-naphthalene dicarboxylic acid, 1,5-naphthalene dicarboxylic acid, 2,6-naphthalene dicarboxylic acid, 1,8-naphthalene dicarboxylic acid, 4,4′-diphenyl dicarboxylic acid, 4,4′-diphenylether dicarboxylic acid, 5-sodium sulfoisophthalic acid, phenylindane dicarboxylic acid, anthracene dicarboxylic acid, phenanthrene dicarboxylic acid, and 9,9′-bis(4-carboxyphenyl) fluorene acid, and ester derivatives thereof.

Examples of (B) the diol component include diol compounds such as aliphatic diols such as ethylene glycol, 1,2-propane diol, 1,3-propane diol, 1,4-butane diol, 1,2-butane diol, or 1,3-butane diol; alicyclic diols such as cyclohexane dimethanol, spiro glycol, or isosorbide; and aromatic diols such as bisphenol A, 1,3-benzene dimethanol, 1,4-benzene dimethanol, or 9,9′-bis(4-hydroxyphenyl) fluorene.

As (A) the dicarboxylic acid component, at least one kind of aromatic dicarboxylic acid is preferably used. It is more preferable to include an aromatic dicarboxylic acid as a main component in the dicarboxylic acid component. Meanwhile, the “main component” refers to the fact that the ratio of an aromatic dicarboxylic acid in the dicarboxylic acid component is 80% by mass or more. Dicarboxylic acids other than the aromatic dicarboxylic acid may be included. Examples of the dicarboxylic acids include an ester derivative of, for example, an aromatic dicarboxylic acid.

As (B) the diol component, at least one kind of aliphatic diol is preferably used. As the aliphatic diol, ethyleneglycol can be included, and it is preferable to include ethyleneglycol as a main component. Meanwhile, the “main component” refers to the fact that the ratio of ethyleneglycol in the diol component is 80% by mass or more.

A preferable amount of an aliphatic diol (for example, ethyleneglycol) used is in a range of from 1.015 mol to 1.50 mol with respect to one mol of the aromatic dicarboxylic acid (for example, terephthalic acid) and an optional ester derivative thereof. The amount used is more preferably in a range of from 1.02 mol to 1.30 mol, and still more preferably in a range of from 1.025 mol to 1.10 mol. If the amount used is in a range of 1.015 mol or more, the esterification reaction proceeds satisfactorily, and if the amount used is in a range of 1.50 mol or less, generation of diethyleneglycol by the dimerization of ethyleneglycol and the like are suppressed, and therefore many properties such as melting point, glass transition temperature, crystallinity, heat resistance, hydrolysis resistance, and weather resistance can be maintained satisfactorily.

It is possible to use a conventionally-known reaction catalyst for the esterification reaction. Examples of the reaction catalyst can include an alkali metal compound, an alkali earth metal compound, a zinc compound, a lead compound, a manganese compound, a cobalt compound, an aluminum compound, an antimony compound, a titanium compound, and a phosphorous compound. Normally, it is preferable to add an antimony compound, a germanium compound, or a titanium compound as a polymerization catalyst in an arbitrary step before completing the production method of the polyester. In such a method, if, for example, a germanium compound is taken as an example, it is preferable to add the germanium compound powder as it is.

For example, in an esterification reaction, an aromatic dicarboxylic acid and an aliphatic diol are polymerized in the presence of a catalyst including a titanium compound. In this esterification reaction, it is preferable to use an organic chelate titanium complex having an organic acid as a ligand as a titanium compound that is a catalyst, and add at least an organic chelate titanium complex, a magnesium compound, and a pentavalent phosphoric acid ester which does not have an aromatic ring as a substituent in this order.

In the beginning, an aromatic dicarboxylic acid and an aliphatic diol are mixed with a catalyst including an organic chelate titanium complex that is a titanium compound before adding a magnesium compound and a phosphorous compound. Since a titanium compound, such as an organic chelate titanium complex, has a high catalyst activity even with respect to esterification reaction, it is possible to perform esterification reaction satisfactorily. At this time, it is possible to add a titanium compound in the mixture of the dicarboxylic acid component and the diol component, or to mix the diol component (or the dicarboxylic acid component) after the dicarboxylic acid component (or the diol component) and a titanium compound are mixed. It is also possible to mix the dicarboxylic acid component, the diol component, and a titanium compound at the same time. The mixing method is not particularly limited, and a conventionally-known method can be used.

More preferable examples of polyester include polyethylene terephthalate (PET) and polyethylene-2,6-naphthalate (PEN), and a still more preferable example is PET. Furthermore, preferable examples of PET include PET polymerized by using one kind or two kinds or more of catalysts selected from a group consisting of germanium (Ge) catalysts, antimony (Sb) catalysts, aluminum (Al) catalysts, and titanium (Ti) catalysts, and Ti catalysts are more preferable.

The Ti catalysts have a high reaction activity, and thus can reduce the polymerization temperature. Therefore, in particular, the Ti catalysts can suppress thermal decomposition of PET and generation of COOH during a polymerization reaction, and therefore, in the polyester film according to the present invention, the Ti catalysts are preferable for adjusting the amount of terminal COOH in a predetermined range.

Examples of the Ti catalysts can include an oxide, a hydroxide, an alkoxide, a carboxylic acid salt, a carbonate, an oxalate, an organic chelate titanium complex, and a halide. The Ti catalysts may be used in combination of two or more kinds of titanium compounds as long as they do not deteriorate the effects of the present invention.

Examples of the Ti catalysts can include a titanium alkoxide, such as tetra-n-propyl titanate, tetra-i-propyl titanate, tetra-n-butyl titanate, tetra-n-butyl titanate tetramer, tetra-t-butyl titanate, tetracyclohexyl titanate, tetraphenyl titanate, and tetrabenzyl titanate, a titanium oxide obtained by the hydrolysis of a titanium alkoxide, a titanium-silicon or zirconium composite oxide obtained by the hydrolysis of a mixture of a titanium alkoxide and a silicon alkoxide or a zirconium alkoxide, titanium acetate, titanium oxalate, potassium titanium oxalate, sodium titanium oxalate, potassium titanate, sodium titanate, a mixture of titanic acid and aluminum hydroxide, titanium chloride, a mixture of titanium chloride and aluminum chloride, titanium acetylacetonate, and an organic chelate titanium complex having an organic acid as a ligand.

When producing a PET by polymerization using a Ti catalyst, it is possible to use a polymerization method described in, for example, JP-A No. 2005-340616, JP-A No. 2005-239940, JP-A No. 2004-319444, Japanese Patent No. 3436268, Japanese Patent No. 3979866, Japanese Patent No. 3780137, and JP-A No. 2007-204538.

When polymerizing polyester, it is preferable to perform polymerization using a titanium (Ti) compound as a catalyst in a range of from 1 ppm to 30 ppm, and more preferably from 2 ppm to 20 ppm, and still more preferably from 3 ppm to 15 ppm. In this case, the polyester film according to the present invention includes titanium in a range of from 1 ppm to 30 ppm.

If the amount of the Ti compound is 1 ppm or more, a preferable IV can be obtained, and if the amount is 30 ppm or less, terminal COOH can be adjusted to satisfy the above range.

For the synthesis of polyester using the Ti compounds, it is possible to apply the methods described in, for example, Japanese Examined Patent Application (JP-B) No. 8-30119, Japanese Patent No. 2543624, Japanese Patent No. 3335683, Japanese Patent No. 3717380, Japanese Patent No. 3897756, Japanese Patent No. 3962226, Japanese Patent No. 3979866, Japanese Patent No. 3996871, Japanese Patent No. 4000867, Japanese Patent No. 4053837, Japanese Patent No. 4127119, Japanese Patent No. 4134710, Japanese Patent No. 4159154, Japanese Patent No. 4269704, and Japanese Patent No. 4313538.

<Titanium Compound>

As a titanium compound which is a catalyst component, at least one kind of an organic chelate titanium complex having an organic acid as a ligand is used. Examples of the organic acid can include citric acid, lactic acid, trimellitic acid, and malic acid. Among them, an organic chelate complex having citric acid or a citric salt as a ligand is preferable.

For example, in the case of using a chelate titanium complex having citric acid as a ligand, only a small amount of foreign substances, such as fine particles, are generated, and compared with other titanium compounds, a polyester resin having a satisfactory polymerization activity and color tone can be obtained. Furthermore, in the case of using a citric acid chelate titanium complex, a polyester resin having a satisfactory polymerization activity and color tone and a small amount of terminal carboxyl groups can be obtained by adding the complex in the esterification reaction step, compared with the case of adding the complex after esterification reaction. Regarding this point, it is assumed that, since a titanium catalyst has a catalyst effect in the esterification reaction, the acid value of an oligomer after the completion of esterification reaction is decreased by adding the complex in the esterification step, and therefore the subsequent polycondensation reaction is performed more efficiently; and that a complex having a citric acid as a ligand has a strong hydrolysis resistance, compared with, for example, a titanium alkoxide, and therefore hydrolysis does not occur during an esterification reaction process, so that the titanium catalyst can effectively act as a catalyst for esterification reaction and polycondensation reaction while maintaining its intrinsic activity.

It is known that, generally, as the amount of terminal COOH increases, hydrolysis resistance deteriorates, but since the amount of terminal carboxyl groups is decreased, improvement in hydrolysis resistance is expected.

The citric acid chelate titanium complex can be easily obtained from a commercially available product, such as VERTEC AC-420 manufactured by Johnson Matthey.

The aromatic dicarboxylic acid and the aliphatic diol can be introduced by preparing a slurry including them and continuously supplying the slurry to the esterification reaction step.

In a preferable embodiment, during esterification reaction, a titanium compound is used as a catalyst in an amount of Ti element of from 1 ppm to 30 ppm, and more preferably from 3 ppm to 20 ppm, and still more preferably from 5 ppm to 15 ppm for polymerization reaction. If the amount of Ti added is 1 ppm or more, it is advantageous in that the polymerization rate becomes fast, and if the amount added is 30 ppm or less, it is advantageous in that satisfactory color tone can be obtained.

Examples of titanium compounds other than an organic chelate titanium complex can include, generally, an oxide, a hydroxide, an alkoxide, a carboxylic acid salt, a carbonate, an oxalate, and a halide. Other titanium compounds may be used together with an organic chelate titanium complex as long as they do not impair the effects of the present invention.

Examples of the titanium compounds can include a titanium alkoxide, such as tetra-n-propyl titanate, tetra-i-propyl titanate, tetra-n-butyl titanate, tetra-n-butyl titanate tetramer, tetra-t-butyl titanate, tetracyclohexyl titanate, tetraphenyl titanate, and tetrabenzyl titanate, a titanium oxide obtained by the hydrolysis of a titanium alkoxide, a titanium-silicon or zirconium composite oxide obtained by the hydrolysis of a mixture of a titanium alkoxide and a silicon alkoxide or a zirconium alkoxide, titanium acetate, titanium oxalate, potassium titanium oxalate, sodium titanium oxalate, a potassium titanate, a sodium titanate, a mixture of a titanic acid and an aluminum hydroxide, a titanium chloride, a mixture of a titanium chloride and an aluminum chloride, and titanium acetylacetonate.

For the synthesis of polyester using such titanium compounds, it is possible to apply the methods described in, for example, Japanese Examined Patent Application Publication (JP-B) No. 8-30119, Japanese Patent No. 2543624, Japanese Patent No. 3335683, Japanese Patent No. 3717380, Japanese Patent No. 3897756, Japanese Patent No. 3962226, Japanese Patent No. 3979866, Japanese Patent No. 3996871, Japanese Patent No. 4000867, Japanese Patent No. 4053837, Japanese Patent No. 4127119, Japanese Patent No. 4134710, Japanese Patent No. 4159154, Japanese Patent No. 4269704, and Japanese Patent No. 4313538.

In the present invention, it is preferable to prepare a polyester resin by a production method of a polyester resin including: an esterification reaction step which includes at least polymerizing an aromatic dicarboxylic acid and an aliphatic diol in the presence of a catalyst containing a titanium compound including an organic chelated titanium complex having an organic acid as a ligand, and adding the organic chelated titanium complex, a magnesium compound, and a pentavalent phosphoric acid ester which does not have an aromatic ring as a substituent, in this order; and a polycondensation step of subjecting an esterification reaction product produced by the esterification reaction step to a polycondensation reaction to produce a polycondensation product.

In this case, since an order of addition of adding an organic chelated titanium complex as a titanium compound, adding a magnesium compound, and then adding a specific pentavalent phosphorus compound is employed in the process of the esterification reaction, the reaction activity of the titanium catalyst can be maintained to be appropriately high, the electrostatic applicability can be imparted by magnesium, and the decomposition reaction in the polycondensation can be effectively suppressed. Therefore, as a result, a polyester resin is obtained which has less coloration and high electrostatic applicability, and exhibits an improvement in yellowing during exposure to high temperature.

Thereby, a polyester resin can be provided which undergoes less coloration during polymerization and during the subsequent melt film forming, so that the yellow tinge is reduced as compared with the conventional polyester resins obtained by antimony (Sb) catalyst systems, which has a color tone and transparency that are comparable to those of the relatively highly transparent polyester resins obtained by germanium catalyst systems, and which has excellent heat resistance. Furthermore, a polyester resin having high transparency and a reduced yellow tinge can be obtained without using a color adjusting material such as a cobalt compound or a colorant.

This polyester resin can be used for applications where the demand for transparency is high (for example, optical films and industrial lith films), and since there is no need to use expensive germanium-based catalysts, a significant reduction in cost can be made. In addition, because the incorporation of catalyst-induced foreign matter that is easily generated in Sb catalyst systems can also be avoided, the occurrence of failure during the film forming process and quality defects are also reduced, so that cost reduction as a result of yield improvement can be made.

For carrying out the esterification reaction, a process of adding an organic chelated titanium complex, which is a titanium compound, and a magnesium compound and a pentavalent phosphorus compound as additives, in this order, is provided. At this time, the esterification reaction proceeds in the presence of the organic chelated titanium complex, and then the magnesium compound is added before the addition of the phosphorus compound.

<Phosphorus Compound>

As the pentavalent phosphorus compound, at least one pentavalent phosphoric acid ester which does not have an aromatic ring as a substituent is preferably used. Examples of the pentavalent phosphoric acid ester according to the invention include trimethyl phosphate, triethyl phosphate, tri-n-butyl phosphate, trioctyl phosphate, tris(triethylene glycol) phosphate, methyl acid phosphate, ethyl acid phosphate, isopropyl acid phosphate, butyl acid phosphate, monobutyl phosphate, dibutyl phosphate, dioctyl phosphate, and triethylene glycol acid phosphate.

Among the pentavalent phosphoric acid esters, a phosphoric acid ester having a lower alkyl group having 2 or fewer carbon atoms as a substituent [(RO)₃P═O; R=alkyl group having 1 or 2 carbon atoms] is preferable, and specifically, trimethyl phosphate and triethyl phosphate are particularly preferable.

Particularly, in the case of using, as a catalyst, a chelated titanium complex having citric acid or a salt thereof as a ligand, a pentavalent phosphoric acid ester leads to a satisfactory polymerization activity and color tone as compared with a trivalent phosphoric acid ester, and in a case in which a pentavalent phosphoric acid ester having 2 or fewer carbon atoms is added, the balance between polymerization activity, color tone and heat resistance can be particularly improved.

The addition amount of the phosphorus compound is preferably an amount that corresponds to a content of P element of from 50 ppm to 90 ppm. The addition amount of the phosphorus compound is more preferably an amount that corresponds to a content of P element of from 60 ppm to 80 ppm, and even more preferably from 65 ppm to 75 ppm.

<Magnesium Compound>

When a magnesium compound is included, electrostatic applicability is enhanced. In this case, coloration is likely to occur; however, according to the invention, coloration is suppressed, and thus excellent color tone and heat resistance can be obtained.

Examples of the magnesium compound include magnesium salts such as magnesium oxide, magnesium hydroxide, magnesium alkoxide, magnesium acetate, and magnesium carbonate. Among them, from the viewpoints of solubility in ethylene glycol, magnesium acetate is most preferable.

In order to impart high electrostatic applicability, the addition amount of the magnesium compound is preferably an amount that corresponds to a content of Mg element of 50 ppm or greater, and more preferably from 50 ppm to 100 ppm. The addition amount of the magnesium compound is, from the viewpoints of imparting electrostatic applicability, preferably an amount that corresponds to a content of Mg element of from 60 ppm to 90 ppm, and even more preferably from 70 ppm to 80 ppm.

In the esterification reaction step, it is particularly preferable to add the titanium compound as the catalyst component and the magnesium compound and phosphorus compound as the additives such that the value Z calculated from the following formula (i) satisfies the following formula (ii) to carry out melt polymerization. Here, the P content is the amount of phosphorus originating from the entirety of phosphorus compounds including the pentavalent phosphoric acid ester which does not have an aromatic ring, and the Ti content is the amount of titanium originating from the entirety of Ti compounds including the organic chelated titanium complex. As such, when a combination of a magnesium compound and a phosphorus compound is selected and used in a catalyst system containing a titanium compound, and the timing of addition and the proportion of addition are controlled, a color tone with less yellow tinge is obtained while the catalytic activity of the titanium compound is maintained to be appropriately high. Thus, a heat resistance can be imparted that does not easily cause yellowing even if the polyester resin is exposed to high temperature during the polymerization reaction or during the subsequent film forming process (during melting).

Z=5×(P content [ppm]/atomic weight of P)−2×(Mg content [ppm]/atomic weight of Mg)−4×(Ti content [ppm]/atomic weight of Ti) (i)

+0≦Z≦+5.0 (ii)

Since the phosphorus compound interacts with the titanium compound as well as the magnesium compound, this value is an index that quantitatively expresses the balance between the three components.

The formula (i) expresses the amount of phosphorus capable of acting on titanium, by subtracting the portion of phosphorus that acts on magnesium, from the total amount of phosphorus capable of reacting. In a case in which the value Z is positive, the system is in a state in which the phosphorus that inhibits titanium is in excess. In a case in which the value is negative, the system is in a state in which phosphorus that is required to inhibit titanium is insufficient. In regard to the reaction, since the respective atoms of Ti, Mg and P are not of equal valence, each of the mole numbers in the formula is weighted by multiplying by the valence.

In the invention, a polyester resin excellent in color tone and resistance to heat coloration can be obtained, while having a reaction activity necessary for the reaction, by using a titanium compound, a phosphorus compound and a magnesium compound that do not require special synthesis or the like and are easily available at low cost.

In the formula (ii), from the viewpoints of further enhancing the color tone and the resistance to heat coloration while maintaining the polymerization reactivity, it is preferable that +1.0≦Z≦+4.0 is satisfied, and it is more preferable that +1.5≦Z≦+3.0 is satisfied.

In a preferable embodiment according to the invention, a chelated titanium complex having citric acid or a citric acid salt as a ligand is added in an amount of from 1 ppm to 30 ppm to the aromatic dicarboxylic acid and the aliphatic diol before the esterification reaction is completed, and then in the presence of the chelated titanium complex, a magnesium salt of weak acid is added in an amount of from 60 ppm to 90 ppm (more preferably, from 70 ppm to 80 ppm), and after the addition, a pentavalent phosphoric acid ester which does not have an aromatic ring as a substituent is further added in an amount of from 60 ppm to 80 ppm (more preferably, from 65 ppm to 75 ppm).

The esterification reaction can be carried out by using a multistage type apparatus having at least two reactors connected in series under the conditions in which ethylene glycol is refluxed, while removing the water or alcohol generated by the reaction from the system.

The esterification reaction may be carried out in a single step, or may be carried out in divided multiple stages.

In a case in which the esterification reaction is carried out in a single step, the esterification reaction temperature is preferably 230° C. to 260° C., and more preferably 240° C. to 250° C.

In a case in which the esterification reaction is carried out in divided multiple stages, the temperature of the esterification reaction at the first reaction tank is preferably 230° C. to 260° C., and more preferably 240° C. to 250° C., and the pressure is preferably 1.0 kg/cm² to 5.0 kg/cm², and more preferably 2.0 kg/cm² to 3.0 kg/cm². The temperature of the esterification reaction at the second reaction tank is preferably 230° C. to 260° C., and more preferably 245° C. to 255° C., and the pressure is preferably 0.5 kg/cm² to 5.0 kg/cm², and more preferably 1.0 kg/cm² to 3.0 kg/cm². Furthermore, in a case in which the esterification reaction is carried out in divided three or more stages, the conditions for the esterification reaction in the middle stages are preferably established to be intermediate between the conditions at the first reaction tank and the conditions at the final reaction tank.

—Polycondensation—

In the polycondensation, a polycondensation product is produced by a polycondensation reaction of the esterification reaction product produced in the esterification reaction.

The polycondensation reaction may be carried out in a single stage, or may be carried out in divided multiple stages.

The esterification reaction product such as oligomers produced in the esterification reaction is continuously subjected to a polycondensation reaction. This polycondensation reaction can be preferably carried out by supplying the esterification reaction product to polycondensation reaction tanks of multiple stages.

For example, the polycondensation reaction conditions, in the case of performing the reaction in a three-stage reaction tank, are that the reaction temperature at the first reaction tank is preferably 255° C. to 280° C., and more preferably 265° C. to 275° C., and the pressure is preferably 100 torr to 10 torr (13.3×10⁻³ MPa to 1.3×10⁻³ MPa), and more preferably 50 torr to 20 torr (6.67×10⁻³ MPa to 2.67×10⁻³ MPa). The reaction temperature at the second reaction tank is preferably 265° C. to 285° C., and more preferably 270° C. to 280° C., and the pressure is preferably 20 torr to 1 torr (2.67×10⁻³ MPa to 1.33×10 MPa), and more preferably 10 torr to 3 torr (1.33×10⁻³ MPa to 4.0×10⁻⁴ MPa). In the third and final reaction tank, the reaction temperature is preferably 270° C. to 290° C., and more preferably 275° C. to 285° C., and the pressure is preferably 10 torr to 0.1 torr (1.33×10⁻³ MPa to 1.33×10⁻⁵ MPa), and more preferably 5 torr to 0.5 torr (6.67×10⁻⁴ MPa to 6.67×10⁻⁵ MPa).

The polycondensation product obtained by polycondensation may be formed into small pieces such as pellets.

When the esterification reaction and polycondensation as described above are carried out, a polyester resin containing titanium atoms (Ti), magnesium atoms (Mg) and phosphorus atoms (P), in which the value Z calculated from the following formula (i) satisfies the following formula (Ii), can be obtained.

Z=5×(P content [ppm]/atomic weight of P)−2×(Mg content [ppm]/atomic weight of Mg)−4×(Ti content [ppm]/atomic weight of Ti) (i)

+0≦Z≦+5.0 (ii)

When the polyester resin satisfies +0≦Z≦+5.0, the balance between the three elements of Ti, P and Mg is appropriately regulated, and therefore, the polyester resin has an excellent color tone and heat resistance (reduction of yellowing under high temperature) and can maintain high electrostatic applicability, while maintaining the polymerization reactivity. Furthermore, according to the invention, a polyester resin having high transparency and reduced yellow tinge can be obtained without using a color adjusting material such as a cobalt compound or a colorant.

The formula (i) quantitatively expresses the balance between the three components of the titanium compound, magnesium compound and phosphorus compound, and represents the amount of phosphorus capable of acting on titanium, by subtracting the portion of phosphorus that acts on magnesium from the total amount of phosphorus capable of reaction. If the value Z is less than +0, that is, if the amount of phosphorus that acts on titanium is too small, the catalytic activity (polymerization reactivity) of titanium is increased. However, heat resistance is decreased, and the polyester resin thus obtained takes on a yellow tinge. Thus, the polyester resin is colored after polymerization, for example, during film forming (during melting), and the color tone is deteriorated. Furthermore, if the value Z exceeds +5.0, that is, if the amount of phosphorus that acts on titanium is too large, the heat resistance and color tone of the polyester resin thus obtained are satisfactory, but the catalytic activity is excessively decreased, and producibility is deteriorated.

In the invention, due to the same reasons as described above, the formula (ii) preferably satisfies 1.0≦Z≦4.0, and more preferably satisfies 1.5≦Z≦3.0.

The measurement of the respective elements of Ti, Mg and P can be carried out by quantifying the respective elements in the PET by using a high resolution inductively coupled plasma mass spectrometer (HR-ICP-MS; AttoM manufactured by SII Nanotechnology, Inc.), and calculating the contents [ppm] from the results thus obtained.

Furthermore, it is preferable that the produced polyester resin further satisfies the following formula (iii).

b value when formed into pellets after polycondensation≦4.0 (iii)

If the b value of the pellets is 4.0 or less when the polyester resin obtained by polycondensation is pelletized, the polyester resin has a reduced yellow tinge and excellent transparency. When the b value is 3.0 or less, the polyester resin has a color tone comparable to that of polyester resins polymerized in the presence of Ge catalysts.

The b value serves as an index representing the color tinge, and is a value measured by using ND-101D (manufactured by Nippon Denshoku Industries Co., Ltd.).

It is also preferable that the polyester resin satisfies the following formula (iv).

Rate of color tone change [Δb/minute]≦0.15 (iv)

If the rate of color tone change [Δb/minute] is 0.15 or less when the pellets of the polyester resin obtained by polycondensation are retained in a molten state at 300° C., the yellowing when the polyester resin is exposed to heat can be suppressed. Thereby, in the case of, for example, forming a film by extruding with an extruder, a film having less yellowing and an excellent color tone can be obtained.

The rate of color tone change is preferably a smaller value, and a value of 0.10 or less is particularly preferable.

The rate of color tone change serves as an index representing a change in color due to heat, and is a value determined by the method described below.

That is, pellets of the polyester resin are fed into a hopper of an injection molding machine (for example, EC100NII manufactured by Toshiba Machine Co., Ltd.), and while the polyester resin is retained in a molten state inside the cylinder (300° C.) and the retention time is changed, the polyester resin is molded into a plate form. The b value of the plate at this time is measured using ND-101D (manufactured by Nippon Denshoku Co., Ltd.). The rate of change [Δb/minute] is calculated based on the changes in the b value.

The polyester resin obtained as described above may further contain an additive such as a light stabilizer, an antioxidant, a UV absorbing agent, a flame retardant, a lubricating agent (fine particles), a nucleating agent (crystallizing agent), a crystallization inhibiting agent, or the like.

—Solid-State Polymerization—

The polyester resin used for the production method of the invention may be those obtained through solid-state polymerization. Solid-state polymerization can be preferably performed using small pieces, such as pellets, of the polyester resin obtained by the above-mentioned synthesis method or commercially available polyester resin. The solid-state polymerization is preferably performed in a condition of a temperature of from 150° C. to 250° C., more preferably from 170° C. to 240° C., and still more preferably from 180° C. to 230° C. and a time of from 1 hour to 50 hours, more preferably from 5 hours to 40 hours, and still more preferably from 10 hours to 30 hours. The solid-state polymerization is preferably performed under vacuum or in a nitrogen flow.

By performing the solid-state polymerization, it is possible to respectively control the moisture content, the degree of crystallinity, the concentration of terminal carboxyl groups (AV: Acid value) and the intrinsic viscosity (IV) of the polyester film in the preferable ranges in the invention.

The solid-state polymerization may be performed by a continuous method (a method that fills a resin in a tower, and heats and slowly circulates it for a predetermined time, and then eject it sequentially) or a batch method (a method that feeds a resin in a vessel and heats it for a predetermined time). Specifically, as the solid-state polymerization, methods described in, for example, Japanese Patent No. 2621563, Japanese Patent No. 3121876, Japanese Patent No. 3136774, Japanese Patent No. 3603585, Japanese Patent No. 3616522, Japanese Patent No. 3617340, Japanese Patent No. 3680523, Japanese Patent No. 3717392, and Japanese Patent No. 4167159 can be used.

The temperature of the solid-state polymerization is preferably from 170° C. to 240° C., and more preferably from 180° C. to 230° C., and still more preferably from 190° C. to 220° C. Temperature in the above ranges is preferable from the standpoint of further highly reducing the terminal COOH amount (AV). The time of the solid-state polymerization is preferably from 5 hours to 100 hours, and more preferably from 10 hours to 75 hours, and still more preferably from 15 hours to 50 hours. The above time is preferable from the standpoint of easily controlling the terminal COOH amount (AV) and the intrinsic viscosity (IV) in the preferable ranges in the present invention. The solid-state polymerization is preferably performed under vacuum or in a nitrogen flow.

The polyester resin used for the production method of the invention preferably has an intrinsic viscosity (IV) of from 0.6 dl/g to 0.9 dl/g, and more preferably from 0.75 dl/g to 0.88 dl/g.

The intrinsic viscosity (IV) is a value calculated by extrapolating the value obtained by dividing the specific viscosity (ηₛₚ=ηᵣ−1), which is calculated by subtracting 1 from the ratio ηᵣ (=η/η₀; relative viscosity) of the solution viscosity (η) to the solvent viscosity (η₀), by a concentration, to a state where the concentration is zero. IV is obtained from the solution viscosity at 25° C. by using an Ubbelohde type viscometer and dissolving polyester in a mixed solvent of 1,1,2,2-tetrachloroethane/phenol (=2/3 [mass ratio]).

The amount of terminal COOH (AV) in the polyester resin used for the production method of the invention is preferably from 5 eq/t to 25 eq/t, and intrinsic viscosity (IV) is preferably from 0.6 dl/g to 0.9 dl/g, and more preferably from 0.75 dl/g to 0.88 dl/g.

The amount of terminal COOH is a value that is measured by titration in accordance with the method described in H. A. Pohl, Anal. Chem. 26 (1954) p. 2145.

The polyester film of the invention is a polyester film obtained by the production method of the invention, and its thickness is preferably 100 μm to 350 μm, more preferably 240 μm to 350 μm, and still more preferably 250 μm or more 340 μm.

Thickness of the polyester film in the present specification is average film thickness measured by using a contact type film thickness meter (manufactured by Yamabun Co., Ltd.). Specifically, by using a contact type film thickness meter, 50 points are sampled at the same interval over 0.5 m in the length direction of the polyester film, another 50 points are sampled at the same interval over the entire width in the width direction of the polyester film (points when the film is equally divided into 50 sections in the width direction), and thickness is measured for the 100 points. An average thickness value is obtained from 100 points and taken as a thickness of the polyester film.

The polyester film of the invention is a polyester film having excellent hydrolysis resistance and excellent voltage resistance.

The hydrolysis resistance of the polyester film of the invention can be evaluated based on rupture elongation retention time. The rupture elongation retention time is obtained from a decrease in rupture elongation when hydrolysis is promoted by forced heating treatment (i.e., thermal treatment).

The polyester film of the invention preferably has a rupture elongation retention time of from 70 hours to 150 hours. When the rupture elongation retention time is 70 hours or longer, progress of hydrolysis is suppressed so that peeling and insufficient adhesion can be prevented. Further, when the rupture elongation retention time is 150 hours or shorter, moisture content in film is lowered and excessive development of crystal structure in film is suppressed so that elasticity and tensile stress are maintained at the level which does not allow peeling.

Preferred rupture elongation retention time is from 80 hours to 145 hours, and more preferably 80 to 140 hours.

Rupture elongation retention time means half time [hr] of rupture elongation at which rupture elongation retention ratio after wet heat treatment (i.e., thermal treatment) at 85° C. and 85% RH is maintained at the level of 50% or more compared to the rupture elongation before wet heat treatment. The rupture elongation retention ratio is obtained by the following formula.

Rupture elongation retention ratio[%]=(Rupture elongation after thermal treatment at 85° C.)/(Rupture elongation before thermal treatment)×100

In the specification, specifically, after carrying out a heating treatment (thermal treatment) at 85° C. and 85% RH for 10 hours to 300 hours with an interval of 10 hours, rupture elongation is measured for each sample after thermal treatment, and the measured value is divided by the rupture elongation before the thermal treatment to give the rupture elongation retention ratio at each thermal treatment time. Then, the rupture elongation retention ratio is plotted as a y axis value against the thermal treatment time as an x axis value, and by connecting the plotted values to each other, the treatment time [hr] until the rupture elongation retention ratio becomes 50% is obtained.

The rupture elongation indicates a value which is obtained by setting a polyester film sample in an elongation tester, elongating the film at 20 mm/min under the environment of 25° C. and 60% RH, measuring the elongation at rupture five times at each of ten points that are obtained by equally dividing the polyester film in the TD direction (that is, transverse direction) while shifting the location of each point in the MD direction (i.e., machine direction) at 20 cm interval to measure 50 points in total, and averaging the obtained values. In addition, by dividing the difference (absolute value) between the maximum value and minimum value of the rupture elongation retention time at 50 points by average value of the rupture elongation retention time at 50 points and expressing it as a percentage value, distribution of rupture elongation retention time [%] can be obtained.

In addition, the withstand voltage of the polyester film of the invention can be evaluated by obtaining partial discharge voltage using a partial discharge tester KPD2050 (manufactured by Kikusui Electronics Co., Ltd.).

[Back Sheet for Solar Cell]

The back sheet for a solar cell of the invention includes the polyester film that is produced by the production method of the invention (i.e., polyester film of the invention), and it may include at least one functional layer such as an easy adhesion layer that easily adheres to an adherend, an UV absorption layer, a white layer having a light reflecting property, or the like.

Since the back sheet for a solar cell of the invention includes the polyester film of the invention, it exhibits stable durability during use for a long period of time.

In the back sheet for a solar cell of the invention, for example, the following functional layer may be formed by coating on the polyester film obtained by the production method of the invention. For forming the layer by coating, known coating techniques, such as a roll coating method, a knife edge coating method, a gravure coating method, and a curtain coating method, can be used.

Before forming the layer by coating, surface treatment (flame treatment, corona treatment, plasma treatment, ultraviolet treatment, etc.) may be performed. The layer is also preferably adhered using an adhesive.

—Easy Adhesion Layer—

The back sheet for a solar cell preferably has the easy adhesion layer at the side facing a sealing material of a cell side substrate in which a solar cell device is sealed by the sealing material when constituting a solar cell module. By providing the easy adhesion layer exhibiting adhesiveness to an adherend (e.g., surface of the sealing material of the cell side substrate in which the solar cell device is sealed with the sealing material) containing the sealing material (particularly an ethylene-vinyl acetate copolymer), the back sheet and the sealing material can be firmly adhered to each other. Specifically, the easy adhesion layer preferably has an adhesion force of 10 N/cm or more and preferably 20 N/cm or more with respect to EVA (ethylene-vinyl acetate copolymer) used as the sealing material.

The easy adhesion layer is required to prevent the separation of the back sheet during the use of a solar cell module and thus preferably has high moisture and heat resistance.

(1) Binder

The easy adhesion layer can contain at least one kind of a binder.

Examples of the binder include polyester, polyurethane, acrylic resin, and polyolefin. In particular, acrylic resin and polyolefin are preferable from the viewpoint of durability. As the acrylic resin, an acryl-silicone composite resin is also preferable. Examples of a preferable binder include the following substances.

Examples of the polyolefin include CHEMIPEARL S-120 and S-75N (both manufactured by Mitsui Chemicals, Inc.). Examples of the acrylic resin include JURYMER ET-410 and SEK 301 (both manufactured by Nihon Junyaku Co., Ltd.). Examples of the acryl-silicone composite resin include CERANATE WSA1060 and WSA1070 (both manufactured by DIC Corporation) and H7620, H7630, and H7650 (all manufactured by Asahi Kasei Chemicals Corporation).

The amount of the binder is preferably in the range of 0.05 to 5 g/m² and particularly preferably in the range of 0.08 to 3 g/m². When the binder amount is 0.05 g/m² or more, favorable adhesion is obtained. When the binder amount is 5 g/m² or lower, a favorable surface condition is obtained.

(2) Particles

The easy adhesion layer can contain at least one kind of particles. The easy adhesion layer preferably contains particles in a proportion of 5% by mass or more based on the mass of the entire layer.

Preferable examples of the particles include inorganic particles, such as silica, calcium carbonate, magnesium oxide, magnesium carbonate, and tin oxide. Particularly, among the above, particles of tin oxide and silica are preferable in that a reduction in adhesion is low when exposed to a moist-heat atmosphere.

The particle diameter of the particles is preferably about 10 to 700 nm and more preferably about 20 to 300 nm. By the use of particles having a particle diameter in the range above, favorable easy adhesion properties can be obtained. The shape of the particles is not particularly limited and particles having a spherical shape, an amorphous shape, and a needle-like shape can be used.

The addition amount of the particles in the easy adhesion layer is preferably 5 to 400% by mass and more preferably 50 to 300% by mass based on the binder in the easy adhesion layer. When the addition amount of the particles is 5% by mass or more, the adhesion when exposed to a moist-heat atmosphere is excellent. When the addition amount of the particles is 1000% by mass or lower, the surface condition of the easy adhesion layer is more favorable.

(3) Crosslinking Agent

The easy adhesion layer can contain at least one kind of a crosslinking agent.

Examples of the crosslinking agent include crosslinking agents, such as an epoxy crosslinking agent, an isocyanate crosslinking agent, a melamine crosslinking agent, a carbodiimide crosslinking agent, and an oxazoline crosslinking agent. Among the above, an oxazoline crosslinking agent is particularly preferable from the viewpoint of securing the adhesion after time has passed in a moist-heat atmosphere.

Specific examples of the oxazoline crosslinking agent include 2-vinyl 2-oxazoline, 2-vinyl-4-methyl-2-oxazoline, 2-vinyl-5-methyl-2-oxazoline, 2-isopropenyl-2-oxazoline, 2-isopropenyl-4-methyl-2-oxazoline, 2-isopropenyl-5-ethyl-2-oxazoline, 2,2′-bis-(2-oxazoline), 2,2′-methylene-bis-(2-oxazoline), 2,2′-ethylene-bis-(2-oxazoline), 2,2′-trimethylene-bis-(2-oxazoline), 2,2′-tetramethylene-bis-(2-oxazoline), 2,2′-hexamethylene-bis-(2-oxazoline), 2,2′-octamethylene-bis-(2-oxazoline), 2,2′-ethylene-bis-(4,4′-dimethyl-2-oxazoline), 2,2′-p-phenylene-bis-(2-oxazoline), 2,2′-m-phenylene-bis-(2-oxazoline), 2,2′-m-phenylene-bis-(4,4′-dimethyl-2-oxazoline), bis-(2-oxazolinyl cyclohexane)sulfide, and bis-(2-oxazolinyl norbornane)sulfide. Furthermore, (co)polymers of these compounds can also be preferably utilized.

Examples of compounds having an oxazoline group include EPOCROS K2010E, K2020E, K2030E, WS500, and WS700 (all manufactured by Nippon Shokubai Kagaku Kogyo Co., Ltd.).

A preferable addition amount of the crosslinking agent in the easy adhesion layer is preferably 5 to 50% by mass and more preferably 20 to 40% by mass based on the binder in the easy adhesion layer. When the addition amount of the crosslinking agent is 5% by mass or more, favorable crosslinking effects are obtained and a reduction in the strength or poor adhesion of a reflective layer is difficult to occur. When the addition amount of the crosslinking agent is 50% by mass or lower, the pot life of a coating liquid can be kept longer.

(4) Additive Agent

To the easy adhesion layer, known mat agents, such as polystyrene, polymethyl methacrylate, and silica, and known surfactants, such as anionic surfactants and nonionic surfactants, may be added as required.

(5) Method for Forming Easy Adhesion Layer

Examples of a method for forming the easy adhesion layer include a method including adhering a polymer sheet having easy adhesion properties to a polyester film or a coating method. The coating method is preferable in that the layer can be formed with ease and in the form of a thin film having high uniformity. As the coating method, known methods, such as gravure coater or bar coater, can be utilized. As a solvent of a coating liquid for use in the coating, water may be acceptable and an organic solvent, such as toluene or methylethylketone, may be acceptable. The solvents may be used singly or as a mixture of two or more kinds thereof.

(6) Physical Properties

The thickness of the easy adhesion layer is not particularly limited and is generally in the range of preferably 0.05 to 8 μm and more preferably 0.1 to 5 μm. When the thickness of the easy adhesion layer is 0.05 μm or more, required easy adhesion properties are easily obtained. When the thickness of the easy adhesion layer is 8 μm or lower, the surface condition can be more favorably maintained.

The easy adhesion layer preferably has transparency from the viewpoint of not impairing the effects of a colored layer (particularly reflective layer) when the colored layer is disposed between the easy adhesion layer and the polyester film.

—UV Absorption Layer—

The back sheet for a solar cell of the invention may be provided with a UV absorption layer containing a UV absorber as described above. The UV absorption layer can be disposed at an arbitrary position on the polyester film.

The UV absorber is preferably dissolved or dispersed with ionomer resin, polyester resin, urethane resin, acrylic resin, polyethylene resin, polypropylene resin, polyamide resin, vinyl acetate resin, cellulose ester resin, or the like for use, and the transmittance of light of 400 nm or lower is adjusted to be 20% or lower.

—Colored Layer—

The back sheet for a solar cell of the invention can be provided with a colored layer. The colored layer is a layer disposed through another layer or directly on the surface of the polyester film, and can be constituted using a pigment or a binder.

The first function of the colored layer is to increase the power generation efficiency of a solar cell module by reflecting light, among incident lights, that reaches the back sheet without being used for power generation in a solar cell, and returning the light to the solar cell. The second function thereof is to improve the decorativeness of the appearance when a solar cell module is viewed from the front surface side. In general, when the solar cell module is viewed from the front surface side, the back sheet is visible in the circumference of a solar cell, and the decorativeness can be increased by providing the colored layer in the back sheet.

(1) Pigment

The colored layer can contain at least one kind of a pigment. The pigment is preferably contained in the range of 2.5 to 8.5 g/m². A more preferable pigment content is in the range of 4.5 to 7.5 g/m². When the content of the pigment is 2.5 g/m² or more, a required colored state is easily obtained, and the reflectance of light or decorativeness can be made more excellent. When the content of the pigment is 8.5 g/m² or lower, the surface condition of the colored layer can be more favorably maintained.

Examples of the pigment include inorganic pigments, such as titanium oxide, barium sulfate, silicon oxide, aluminum oxide, magnesium oxide, calcium carbonate, kaolin, talc, ultramarine, Prussian blue, and carbon black and organic pigments, such as phthalocyanine blue and phthalocyanine green. Among these pigments, a white pigment is preferable from the viewpoint of constituting the colored layer as a reflective layer that reflects the entering sunlight. Examples of the white pigments include titanium oxide, barium sulfate, silicon oxide, aluminum oxide, magnesium oxide, calcium carbonate, kaolin, and talc.

The average particle diameter of the pigment is preferably 0.03 to 0.8 μm and more preferably about 0.15 to 0.5 μm. When the average particle diameter is outside the range above, the light reflection efficiency may be decreased.

When the colored layer is constituted as the reflective layer that reflects the entering sunlight, a preferable addition amount of the pigment in the reflective layer cannot be generally determined because the preferable amount varies depending on the type or average particle diameter of the pigment to be used, but the amount is preferably 1.5 to 15 g/m² and more preferably about 3 to 10 g/m². When the addition amount is 1.5 g/m² or more, a required reflectance is easily obtained. When the addition amount is 15 g/m² or lower, the strength of the reflective layer can be maintained at a higher degree.

(2) Binder

The colored layer can contain at least one kind of a binder. The amount of the binder when the binder is included is in the range of preferably 15 to 200% by mass and more preferably 17 to 100% by mass based on the pigment. When the binder amount is 15% by mass or more, the strength of the colored layer can be more favorably maintained. When the binder amount is 200% by mass or lower, sufficient reflectance or decorativeness may be obtained.

Examples of a binder suitable for the colored layer include polyester, polyurethane, acrylic resin, and polyolefin. As the binder, acrylic resin and polyolefin are preferable from the viewpoint of durability. As the acrylic resin, an acryl-silicone composite resin is also preferable. Examples of a preferable binder include the following substances.

Examples of the polyolefin include CHEMIPEARL S-120 and S-75N (both manufactured by Mitsui Chemicals, Inc.). Examples of the acrylic resin include JURYMER ET-410 and SEK 301 (both manufactured by Nihon Junyaku Co., Ltd.). Examples of the acryl-silicone composite resin include CERANATE WSA1060 and WSA1070 (both manufactured by DIC Corporation) and H7620, H7630, and H7650 (all manufactured by Asahi Kasei Chemicals Corporation).

(3) Additive Agent

To the colored layer, a crosslinking agent, a surfactant, a filler, and the like may be added, as required, in addition to the binder and the pigment.

Examples of the crosslinking agent include crosslinking agents, such as an epoxy crosslinking agent, an isocyanate crosslinking agent, a melamine crosslinking agent, a carbodiimide crosslinking agent, and an oxazoline crosslinking agent. The addition amount of the crosslinking agent in the colored layer is preferably 5 to 50% by mass and more preferably 10 to 40% by mass based on the binder in the colored layer. When the addition amount of the crosslinking agent is 5% by mass or more, favorable crosslinking effects can be obtained and the strength or the adhesion of the colored layer can be maintained at a high degree. When the addition amount of the crosslinking agent is 50% by mass or lower, the pot life of a coating liquid can be maintained for a longer time.

Examples of the surfactant include known anionic surfactants and nonionic surfactants. The addition amount of the surfactant is preferably 0.1 to 15 mg/m² and more preferably 0.5 to 5 mg/m². When the addition amount of the surfactant is 0.1 mg/m² or more, cis sing is effectively suppressed. When the addition amount of the surfactant is 15 mg/m² or less, the adhesion is excellent.

To the colored layer, a filler, such as silica, may be added in addition to the pigment. The addition amount of the filler is preferably 20% by mass or lower and more preferably 15% by mass or lower based on the binder in the colored layer. By containing the filler, the strength of the colored layer can be increased. When the addition amount of the filler is 20% by mass or lower, the pigment ratio can be maintained, and thus favorable light reflection properties (reflectance) and decorativeness are obtained.

(4) Method for Forming Colored Layer

Examples of a method for forming the colored layer include a method including adhering a polymer sheet containing a pigment to a polyester film, a method including co-extruding the colored layer during the formation of the polyester film, and a coating method. The coating method is preferable in that the layer can be formed with ease and in the form of a thin film having high uniformity. As the coating method, known methods, such as gravure coater or bar coater, can be utilized. As a solvent of a coating liquid for use in the coating method, water may be acceptable and an organic solvent, such as toluene or methylethylketone, may be acceptable. However, it is preferable to use water as a solvent from the viewpoint of an environmental load.

The solvents may be used singly or as a mixture of two or more kinds thereof.

(5) Physical Properties

The colored layer is preferably constituted as a white layer (light reflection layer) containing a white pigment. The reflectance of 550 nm light in the case of the reflective layer is preferably 75% or more. When the reflectance is 75% or more, the sunlight that passes through a solar cell and is not used for power generation can be returned to the cell, and thus an effect of increasing the power generation efficiency is high.

The thickness of the white layer (light reflection layer) is preferably 1 to 20 μm, more preferably 1 to 10 μm, and still more preferably about 1.5 to 10 μm. When the film thickness is 1 μm or more, required decorativeness and reflectance are easily obtained. When the film thickness is 20 μm or lower, satisfactory surface condition may be obtained.

—Undercoat Layer—

In the back sheet for a solar cell of the invention, an undercoat layer can be provided. The undercoat layer can be provided between the colored layer and the polyester film, for example, when the colored layer is provided. The undercoat layer can be constituted using a binder, a crosslinking agent, a surfactant, and the like.

Examples of binder contained in the undercoat layer include polyester, polyurethane, acrylic resin, and polyolefin. To the undercoat layer, crosslinking agents, such as an epoxy crosslinking agent, an isocyanate crosslinking agent, a melamine crosslinking agent, a carbodiimide crosslinking agent, or an oxazoline crosslinking agent, a surfactant, such as an anionic surfactant or a nonionic surfactant, and a filler, such as silica, may be added in addition to the binder.

Methods for forming the undercoat layer by coating or solvents of a coating liquid to be used are not particularly limited.

As the coating method, a gravure coater or a bar coater can be utilized, for example. The solvents may be water or may be organic solvents, such as toluene or methyl ethyl ketone. The solvents may be used singly or as a mixture of two or more kinds thereof.

The coating may be performed to the polyester film after biaxially stretched or may be performed to the polyester film after uniaxially stretched. In this case, the polyester film may be further stretched after coating in a direction different from the first stretching direction, and formed into a film. The polyester film may be stretched in two directions after the coating is performed to the polyester film before stretching.

The thickness of the undercoat layer is in the range of preferably 0.05 μm to 2 μm and more preferably about 0.1 μm to about 1.5 μm. When the film thickness is 0.05 μm or more, required adhesion is easily obtained. When the film thickness is 2 μm or lower, the surface condition can be favorably maintained.

—Fluororesin Layer and Silicon Resin Layer—

In the back sheet for a solar cell of the invention, at least one of a fluororesin layer or a silicon (Si) resin layer is preferably provided. By providing the fluororesin layer or the Si resin layer, dirt is prevented and the weather resistance is improved on the surface of polyester. Specifically, it is preferable to have a fluororesin coating layer described in JP-A Nos. 2007-35694 and 2008-28294 and WO2007/063698.

A fluororesin film, such as TEDLAR (manufactured by DuPont), is also preferably adhered thereto.

The thickness of each of the fluororesin layer and the Si resin layer is in the range of preferably from 1 μm to 50 μm, more preferably from 1 μm to 40 μm, and still more preferable from 1 μm to 10 μm.

—Inorganic Layer—

An embodiment in which an inorganic layer is provided in the back sheet for a solar cell of the invention is also preferable. By providing the inorganic layer, a moisture resistance function or a gas barrier function for preventing entrance of water or gas into polyester can be imparted. The inorganic layer may be provided at any of the front side or the back side of the polyester film. From the viewpoint of waterproof, moistureproof, or the like, the inorganic layer is preferably provided at the side of the polyester film opposite to the side (the side at which the colored layer or the easy adhesion layer is formed) facing the cell side substrate.

The moisture permeation amount (moisture permeability) of the inorganic layer is preferably 10° g/m²·d to 10⁻⁶ g/m²·d, more preferably 10¹ g/m²·d to 10⁻⁵ g/m²·d, and still more preferably 10² g/m²·d to 10⁻⁴ g/m²·d.

In order to form the inorganic layer having such moisture permeability, the following dry method is preferable.

Examples of methods for forming a gas barrier inorganic layer (hereinafter also referred to as a gas barrier layer) by a dry method include vacuum evaporation methods, such as a resistance heating evaporation, an electron beam evaporation, an induction heating evaporation, and an assist method using plasma or ion beam, sputtering methods, such as a reactive sputtering method, an ion beam sputtering method, and an ECR (electron cyclotron) sputtering method, physical vapor deposition methods (PVD method), such as an ion plating method, and chemical vapor deposition methods (CVD method) utilizing heat, light, plasma, or the like. In particular, the vacuum evaporation method including forming a film by a vapor deposition method under vacuum is preferable.

Here, when materials forming the gas barrier layer contain inorganic oxides, inorganic nitrides, inorganic oxynitrides, inorganic halides, inorganic sulfides, and the like as the main component, a material having the same composition as the composition of the gas barrier layer to be formed can be directly volatilized and deposited on a base material or the like. However, when the formation is carried out by this method, the composition sometimes changes during the volatilization, and as a result the formed film sometimes does not exhibit uniform properties. Therefore, examples include (1) a method including volatilizing a material having the same composition as that of the barrier layer to be formed as the volatilization source while introducing oxygen gas in the case of inorganic oxides, nitrogen gas in the case of inorganic nitrides, a mixed gas of oxygen gas and nitrogen gas in the case of inorganic oxynitrides, halogen gas in the case of inorganic halides, or sulfur gas in the case of inorganic sulfides into a system in an auxiliary manner, (2) a method including introducing oxygen gas in the case of inorganic oxides, nitrogen gas in the case of inorganic nitrides, a mixed gas of oxygen gas and nitrogen gas in the case of inorganic oxynitrides, halogen gas in the case of inorganic halides, or sulfur gas in the case of inorganic sulfides into a system while volatilizing an inorganic substance as the volatilization source, and depositing them on the surface of a base material while reacting the inorganic substance and the introduced gas, (3) a method including volatilizing an inorganic substance as the volatilization source, forming a layer of the inorganic substance, and holding the layer in an oxygen gas atmosphere in the case of inorganic oxides, a nitrogen gas atmosphere in the case of inorganic nitrides, a mixed gas atmosphere of oxygen gas and nitrogen gas in the case of inorganic oxynitrides, a halogen gas atmosphere in the case of inorganic halides, or a sulfur gas atmosphere in the case of inorganic sulfides, and reacting the inorganic substance layer and the introduced gas.

Among the above, (2) or (3) is more preferably used in that volatilization from the volatilization source is easily performed. The method (2) is more preferably used in that the film quality is easily controlled. When the barrier layer is an inorganic oxide, a method including volatilizing an inorganic substance as the volatilization source to form a layer of the inorganic substance, and leaving the layer in the air to thereby naturally oxidize the inorganic substance is also preferable in that the formation is easily performed.

It is also preferable to adhere aluminum foil thereto to be used as a barrier layer. The thickness is preferably from 1 μm to 30 μm. When the thickness is 1 μm or more, water is difficult to permeate into the polyester film with time (thermal treatment) and hydrolysis is difficult to occur. When the thickness is 30 μm or lower, the thickness of the barrier layer does not become excessively large and no deformation is generated in the film due to the stress of the barrier layer.

[Solar Cell Module]

The solar cell module of the invention includes a solar cell device, which converts the light energy of sunlight to electric energy, between a transparent substrate on which sunlight is incident and the polyester film of the invention (a back sheet for a solar cell) described hereinabove. The gap between the substrate and the polyester film may be sealed up with a resin such as an ethylene-vinyl acetate copolymer or the like (so-called sealant).

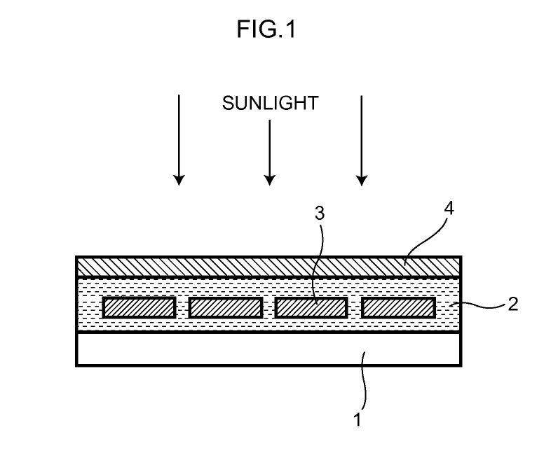

The solar cell module may have a configuration in which, as illustrated in FIG. 1, power generation devices (solar cell devices) 3 that are connected to metal wires (not illustrated in the FIGURE) taking electricity out from the devices are sealed with a sealing material 2 such as an ethylene vinyl acetate copolymer (EVA) resin; they are sandwiched between a transparent substrate 4 such as glass and a back sheet 1 that includes the polyester film of the present invention; and they are bonded together.

Members other than the solar cell module, back sheet, and solar cells are described in detail, for example, in “Solar Power System Constitutive Materials” (by Eiichi Sugimoto, Kogyo Chosakai Publishing, 2008).

The transparent substrate may be any one having a light transmittance that allows for sunlight transmission therethrough, and may be suitably selected from light-transmitting substrates. From the viewpoint of the power generation efficiency, those having a higher light transmittance are preferred, and more preferred are glass substrates and transparent resins such as acrylic resins.

As the solar cell device, various known solar cell devices are employable here, including, for example, silicon-based devices of single-crystal silicon, polycrystal silicon, amorphous silicon or the like, as well as III-V Group or II-VI Group compound semiconductor devices of copper-indium-gallium-selenium, copper-indium-selenium, cadmium-tellurium, gallium-arsenic, or the like.

### EXAMPLES

The invention will be described more specifically with reference to Examples. However, the invention should not be limitedly interpreted by Examples to be mentioned below as long as it is within the scope of the invention. Further, unless specifically described otherwise, “part” is based on mass.

### Examples 1 to 20 and Comparative Examples 1 to 6

Each polyester film of Examples and Comparative Examples was prepared as described below, and then a back sheet provided with the polyester film and a solar cell module provided with the back sheet were produced.

[Preparation of Polyester Film]

(Preparation of Polyester Film of Example 1)

<Synthesis of Polyester Resin 1 as Raw Material>

As described below, a polyester resin (Ti catalyst-based PET) was obtained using a continuous polymerization apparatus based on direct esterification method in which terephthalic acid and ethylene glycol are directly reacted with each other, water is distilled off, and after esterification, polycondensation is carried out under reduced pressure.

(1) Esterification Reaction

High purity terephthalic acid in an amount of 4.7 tons and ethylene glycol in an amount of 1.8 tons were mixed over 90 minutes to form slurry in a first esterification reaction tank. The slurry was continuously supplied at a flow rate of 3800 kg/hour to a first esterification reaction tank. Further, an ethylene glycol solution of a citric acid chelate titanium complex having citric acid coordinated to Ti metal (“VERTEC AC-420”, manufactured by Johnson Matthey Corp.) was supplied continuously. Reaction was carried out at a temperature of 250° C. inside the reaction tank and an average retention time of about 4.3 hours with stirring. The citric acid chelate titanium complex was continuously added in a manner that the addition amount of Ti element was 9 ppm. The acid value of the resulting oligomer was 600 eq/t.

The resulting reaction mixture was transferred to a second esterification reaction tank, and reacted with stirring at a temperature of 250° C. inside the reaction tank and an average retention time of 1.2 hours, so that an oligomer having an acid value of 200 eq/t was obtained. The inside of the second esterification reaction tank was divided into three zones. At a second zone, an ethylene glycol solution of magnesium acetate was continuously supplied in a manner that the addition amount of Mg element was 75 ppm. After that, at a third zone, an ethylene glycol solution of trimethyl phosphate was continuously supplied in a manner that the addition amount of P element was 65 ppm.

(2) Polycondensation Reaction

The esterification reaction product obtained above was supplied continuously to a first polycondensation reaction tank. Polycondensation was carried out with stirring at a reaction temperature of 270° C., a pressure of 20 Ton (2.67×10⁻³ MPa) inside the reaction tank, and an average retention time of about 1.8 hours.

Further, the reaction product was transferred to a second polycondensation reaction tank. In this reaction tank, reaction (polycondensation) was carried out with stirring at a temperature of 276° C. inside the reaction tank, a pressure of 5 Ton (6.67×10⁻⁴ MPa) inside the reaction tank, and a retention time of about 1.2 hours.

After that, the reaction product was transferred to a third polycondensation reaction tank. In this reaction tank, reaction (polycondensation) was carried out at a temperature of 278° C. inside the reaction tank, a pressure of 1.5 Ton (2.0×10⁻⁴ MPa) inside the reaction tank and a retention time of 1.5 hours, so that a reaction product (polyethylene terephthalate (PET)) was obtained.

Then, the resulting reaction product was extruded into cold water in a strand form and immediately cut, so that polyester resin pellets <cross section: about 4 mm of long axis and about 2 mm of short axis, length: about 3 mm> were prepared. Further, these pellets may be vacuum-dried at 180° C., fed into a raw material hopper of a monoaxial kneading extruder that has a screw in a cylinder thereof, and extruded so as to form a film.

The resulting polyester resin was measured as described below with a high resolution inductively coupled plasma mass spectrometer (HR-ICP-MS: “ATTOM” manufactured by SII NanoTechnology Inc.). The results were: Ti=9 ppm, Mg=75 ppm, and P=60 ppm. P was slightly reduced as compared with the initial addition amount. Volatilization during polymerization may be considered.

As for the obtained polymer, intrinsic viscosity (IV)=0.65, amount of terminal COOH (AV)=22 eq/ton, melting point=257° C., and solution haze=0.3%.

—Solid-State Polymerization—

The PET sample polymerized above was pelletized (diameter of 3 mm, and length of 7 mm), and part of the obtained resin pellets were subjected to solid-state polymerization in batch mode.

After the resin pellets were fed into a vessel, the solid-state polymerization was performed under vacuum and under stirring according to the following conditions.

After pre-crystallization treatment at 150° C., solid-state polymerization reaction at 190° C. was performed for 30 hours.

As for the obtained polyester resin (PET-1) after solid-state polymerization, intrinsic viscosity (IV)=0.78 dl/g, and amount of terminal COOH (AV)=27 eq/ton.

—Formation of Unstretched Film—

PET-1 after the solid state polymerization as describe above was dried, so that the water content thereof was reduced to 20 ppm or less. After that, PET-1 was fed into a hopper of a monoaxial kneading extruder with a diameter of 50 mm, melted at 300° C., and extruded. The resulting melted product (melt) was passed through a gear pump and a filter (having a pore diameter of 20 μm), and then the melt was extruded from a die onto a cooling (chill) cast drum according to the following conditions (a) to (c). Note that, the extruded melt was adhered to the cooling cast drum by using the electrostatic charging method.

<Conditions>

(a) Thickness of Melt Extruded from Die

Discharge amount of an extruder and height of die slit were adjusted so as to give the unstretched film having a thickness of 2.52 mm.

(b) Melt Cooling Rate

By adjusting temperature of a cooling cast drum and temperature and amount of cold air supplied from an auxiliary cooling device which had been installed to face the cooling cast drum, and supplying the cold air to the melt film to promote the cooling, the cooling rate was adjusted to 600° C./min. The cooling rate was obtained from the temperature of extruded melt at a landing point on a cast drum and the temperature thereof at a peeling point on a cast drum.

(c) Temperature Unevenness in Cooling Roll

A coolant (e.g., water) was passed through a hollow chill roll (cooling cast drum) for temperature control. At that time, by including a baffle inside the chill roll, temperature unevenness was created. While measuring the surface temperature of the chill roll with a non-contact type thermometer (thermo viewer), a baffle was adjusted to make the temperature unevenness.

Glass transition temperature of the obtained unstretched polyester film was 75° C.

—Stretching of Unstretched Film—

The atmospheric temperature around a pre-heating roll was controlled using a hot air generator having a ceramic heater. By supplying hot air at 42° C., the temperature was adjusted to 30° C. Thereafter, with fifteen pre-heating rolls which had a diameter of 180 mm to 200 mm, an installation interval (interplanar distance between rollers) of 10 mm, and a surface temperature of 75 to 85° C., the unstretched film obtained above was transferred. At that time, the difference between the surface temperature and the central temperature of the film, in which the temperatures were measured according to the method described above, was 3.5° C.

After that, while the pre-heated film was heated to 90° C. with a near IR heater, the film was stretched in the longitudinal direction (transfer direction) with a stretch ratio of 3.5 by two stretching rolls having different circumferential speed that were installed before and after the near IR heater.

Further, in the Examples and the Comparative Examples, the thickness (mm), the difference between the surface temperature (° C.) and the central temperature (° C.), and the mean temperature (° C.) of each unstretched film, and the surrounding atmospheric temperature (° C.) of the pre-heating roll were obtained as follows. The results are given in Table 1.

<Thickness>

A thickness of an unstretched film was measured by using an automatic thickness measuring device (“WEBFREX”, manufactured by Yokogawa Electric Corporation) which was installed at the outlet of the cast drum.

<Difference Between Surface Temperature and Central Temperature>

The film surface temperature was measured by attaching a thermocouple on two surfaces of each of the polyester films of the Examples and the Comparative Examples.

When measuring the central temperature of the film, the thermocouple was embedded in the central portion in the thickness direction of a film to be measured.

The difference between a surface temperature and a central temperature is a value (° C.) which is obtained by subtracting the measured value of the central temperature from the measured value of the surface temperature.

Further, as a thermocouple, “K thermocouple” manufactured by Nagoya Scientific Instruments Co., Ltd. was used.

The measurement range of each of the surface temperature and the central temperature of the film was from a point that was 5 m behind the stretching start point (in length in the film transfer direction) to the stretching start point. The data was obtained every 100 ms within the measurement range, and the average value of the difference between the surface temperature and the central temperature at each point was taken as the difference between the surface temperature and the central temperature of the film.

<Mean Temperature (° C.)>

The average value of the surface temperature and the central temperature of the unstretched polyester film as measured above was taken as a mean temperature T1 (° C.) of an unstretched polyester film.

<Surrounding Atmospheric Temperature (° C.) of Pre-Heating Roll>

The temperature was measured with a thermocouple in a space which is 10 cm apart in perpendicular direction from the film surface at the measurement point which was a central point between a stretching roll disposed at the upstream side in the transfer direction and a pre-heating roll disposed one roll behind the stretching roll and which was a central point in the width direction of the film.

—Thermal Fixation and Thermal Relaxation—

Subsequently, the stretched film after completing longitudinal stretching and transverse stretching was thermally fixed at 210° C. (time for thermal fixation: 10 sec). Further, after the thermal fixation, thermal relaxation was carried out while narrowing a tenter width (temperature for thermal relaxation: 210° C.).

—Winding—

After thermal fixation and thermal relaxation, both ends of the film were subjected to 20 cm trimming respectively. After that, a press processing (knurling) of 10 mm width was applied on both ends of the film, and then the film was wound up at a tension of 25 kg/m. Note that, the film width was 2.5 m and the film length was 2000 m.

As a result, the polyester film of Example 1 was obtained.

(Preparation of Polyester Film of Examples 2 and 3)

Each polyester film of Examples 2 and 3 was obtained in the same manner as in

Example 1 except that, when forming an unstretched film of Example 1, a thickness of an unstretched film was changed to the thickness described in the following Table 1 by adjusting a discharge amount of an extruder and die slit height and line, and cooling rate was suitably adjusted for each thickness.

(Preparation of Polyester Film of Examples 4 to 7)

Each polyester film of Examples 4 to 7 was obtained in the same manner as in Example 1 except that, in Example 1, the difference between the surface temperature and the central temperature of the film subjected to stretching was changed to the temperature described in the following Table 1 by adjusting the temperature of a pre-heating roll.

(Preparation of polyester film of Examples 8 to 10)

Each polyester film of Examples 8 to 10 was obtained in the same manner as in Example 1 except that, in Example 1, the mean temperature T1 of the film subjected to stretching was adjusted to the mean temperature T1 described in the following Table 1 by adjusting the temperature of a pre-heating roll and the surrounding atmospheric temperature of the pre-heating roll.

(Preparation of Polyester Film of Examples 11 to 14)

Each polyester film of Examples 11 to 14 was obtained in the same manner as in Example 1 except that, in Example 1, the surrounding atmospheric temperature of the pre-heating roll was changed to the temperature described in the following Table 1.

(Preparation of Polyester Film of Examples 15 to 20)

Each polyester film of Examples 15 to 20 was obtained in the same manner as in Example 1 except that, in Example 1, the intrinsic viscosity or an amount of terminal COOH of the polyester resin which constituted an unstretched film was adjusted to the value described in Table 1.

(Preparation of Polyester Film of Comparative Examples 1 and 2)

Each polyester film of Comparative Examples 1 and 2 was obtained in the same manner as in Example 1 except that, in Example 1, the thickness of the unstretched film was changed to the thickness described in Table 1.

(Preparation of Polyester Film of Comparative Examples 3 and 4)

Each polyester film of Comparative Examples 3 and 4 was obtained in the same manner as in Example 1 except that, in Example 1, the difference between the surface temperature and the central temperature of the film in a stretching step was adjusted to the value described in Table 1.

(Preparation of Polyester Film of Comparative Examples 5 and 6)

Each polyester film of Comparative Examples 5 and 6 was obtained in the same manner as in Example 1 except that, in Example 1, the mean temperature T1 of the film subjected to stretching was adjusted to the value described in Table 1.

—Evaluation of Film—

Each polyester film after stretching obtained in the Examples and the Comparative Examples was evaluated in terms of film surface smoothness (presence or absence of scratches and presence or absence of protrusions caused by adhesion), rupture elongation retention time, and withstand voltage.

Further, from the evaluation result of rupture elongation retention time and evaluation result of withstand voltage, weather resistance was evaluated as an overall evaluation of each polyester film.

Each measurement result and evaluation result are given in the following Table 1.

Measurement and evaluation of each physical property was performed according to the following method.

(AV: Measurement of Amount of Terminal COOH)

According to neutralizing titration method, the amount of terminal COOH was measured as follows.

Specifically, the unstretched polyester film was dissolved in benzyl alcohol and a phenol red indicator was added. Then, titration was performed with a water/methanol/benzyl alcohol solution of sodium hydroxide.

(IV: Measurement of Intrinsic Viscosity)

The intrinsic viscosity (IV) is a value calculated by extrapolating the value obtained by dividing the specific viscosity (ηₛₚ=ηᵣ−1), which is calculated by subtracting 1 from the ratio ηᵣ (=η/η0; relative viscosity) of the solution viscosity (η) to the solvent viscosity (η₀), by a concentration, to a state where the concentration is zero. IV was obtained from the solution viscosity at 25° C. by using an Ubbelohde type viscometer and dissolving the raw polyester resin used in the Examples or the Comparative Examples in a mixed solvent of 1,1,2,2-tetrachloroethane/phenol (=2/3 [mass ratio]).

(Evaluation of Film Surface Smoothness)

Each polyester film after stretching was observed with a naked eye through a laser microscope manufactured by Keyence Corporation. Within the range of 100 mm×100 mm in the central portion in the width direction, the number of scratches and the number of protrusions caused by adhesion were counted.

With regard to the scratches occurred, when there are five or more scratches having a length of 1 mm or more and a depth of 0.1 μm or more, it is deemed that film surface smoothness is not present. With regard to the protrusions caused by adhesion, when there are five or more protrusions having a length of 1 mm or more but less than 5 mm and a height of 0.1 μm or more, it is deemed that film surface smoothness is not present.

(Evaluation of Hydrolysis Resistance According to Half Life of Rupture Elongation Retention Ratio)

Each polyester film after stretching was subjected to a thermal treatment for 105 hours under an atmosphere of 85° C. and 85% RH, and the rupture elongation before the thermal treatment and the rupture elongation after the thermal treatment were measured for each sample.

When measuring rupture elongation (%), a sample piece with a size of 10 mm×200 mm was cut out from the polyester film, and the sample piece was elongated at 0.5 mm/min and an initial sample length of 50 mm.

Based on the obtained measured values, the rupture elongation after the thermal treatment was divided by the rupture elongation before the thermal treatment, and the rupture elongation retention ratio was obtained for each thermal treatment time based on the following formula. Then, the rupture elongation retention ratio is plotted as a y axis value against the thermal treatment time as an x axis value, and by connecting the plotted values to each other, the treatment time [hr; half life of rupture elongation retention ratio] until the rupture elongation retention ratio becomes 50% was obtained.

Rupture elongation retention ratio [%]=(Rupture elongation after thermal treatment at 85° C.)/(Rupture elongation before thermal treatment)×100

A longer half-life (hr) of rupture elongation retention ratio indicates a better hydrolysis resistance of a polyester film.

As for the hydrolysis resistance, maintaining the rupture elongation retention ratio of 50% or more for 2000 hours or longer but less than 3000 hours is within the range that is practically allowable. Maintaining it for 3000 hours or longer is more preferable.

(Evaluation of Withstand Voltage)

Each polyester film after stretching was kept overnight in a room at 23° C., 65% RH, and then used as a sample to measure a partial discharge voltage using a partial discharge tester KPD2050 (manufactured by Kikusui Electronics Co., Ltd.).

The measurement was made at arbitrarily selected 10 spots on the film surface in each of a case in which one surface of a sample film is employed as an upper electrode side and a case in which it is employed as a lower electrode side. An average value of the measured values was obtained, and a higher value of the respective average values was taken as a partial discharge voltage V0. Conditions for the test were as follows.

### <Conditions for Test>

As the output voltage application pattern on an output sheet, a pattern is selected which consists of three steps in which the first step is a pattern of simply increasing the voltage from 0 V to a pre-determined test voltage, the second step is a pattern of maintaining the pre-determined test voltage, and the third step is a pattern of simply lowering the voltage from the pre-determined test voltage to 0 V.

Frequency is 50 Hz.

Test voltage is 1 kV.

First step time T1 is 10 sec, second step time T2 is 2 sec, and third step time T3 is 10 sec.

Counting method on a pulse count sheet is “+” (plus) and detection level is 50%.

Charge amount on range sheet is range 1000 pc.

As for the protection sheet, check voltage check box and enter 2 kV. Further, pulse count is 100000.

In the measurement mode, the initiation voltage is 1.0 pc and the extinction voltage is 1.0 pc.

The target range of withstand voltage is such that the partial discharge voltage V0 measured as described above is 700 V or higher. More preferably, it is 1000 V or higher.

(Overall Evaluation: Weather Resistance)

Overall evaluation was made based on the following evaluation criteria.

—Evaluation Criteria—

A: A case in which rupture elongation retention time is 3000 hours or longer and partial discharge voltage is 1000 V or higher

B: A case in which rupture elongation retention time is 2000 hours or longer and partial discharge voltage is 700 V or higher

C: A case other than A and B.

Overall evaluation of A or B means that the polyester film has excellent weather resistance.

[Production of Back Sheet]

On the one surface of each polyester film of the Examples and the Comparative Examples, the following (i) reflection layer and (ii) easy adhesion layer were applied in this order by coating.

(i) Reflection Layer (Colored Layer)

At first, components having the following composition were mixed and subjected to dispersion treatment for 1 hour with a dyno-mill disperser, so that pigment dispersion was prepared.

### <Formulation of Pigment Dispersion>

Titanium dioxide . . . 39.9% by mass (“TIPAQUE R-780-2”, manufactured by ISHIHARA SANGYO KAISHA, LTD., 100% of solid matter content)

Polyvinyl alcohol . . . 8.0% by mass (“PVA-105”, manufactured by KURARAY CO., LTD., 10% of solid matter content)

Surfactant . . . 0.5% by mass (“DEMOL EP”, manufactured by Kao Corp., 25% of solid matter content)

Distilled water . . . 51.6% by mass.

Then, using the resulting pigment dispersion and mixing components having the following composition, a coating liquid for forming a reflection layer was prepared.

### <Formulation of Coating Liquid for Forming Reflection Layer>

Above pigment dispersion . . . 71.4 parts by mass

Polyacrylic resin water dispersion liquid . . . 17.1 parts by mass (binder: “JURYMER ET410”, manufactured by Nihon Junyaku Co., Ltd., 30% by mass of solid matter content)

Polyoxyalkylene alkyl ether . . . 2.7 parts by mass (“NAROACTY CL95”, manufactured by Sanyo Chemical Industries, Ltd., 1% by mass of solid matter content)

Oxazoline compound . . . 1.8 parts by mass (cross-linking agent: “EPOCROS WS-700”, manufactured by NIPPON SHOKUBAI CO., LTD., 25% by mass of solid matter content)

Distilled water . . . 7.0 parts by mass

Thus obtained coating liquid for forming a reflection layer was applied on a sample film, and dried at 180° C. for 1 minute to form a reflection layer (dry thickness=5 μm; white layer) with a titanium dioxide coating amount of 6.5 g/m².

(ii) Easy Adhesion Layer

Components with the following composition were mixed to prepare a coating liquid for forming an easy adhesion layer. The coating liquid was applied in a coating amount of binder of 0.09 g/m² onto the reflection layer. Then, one minute drying at 180° C. was performed. In this way, an easy adhesion layer with a dry thickness of 1 μm was formed.

### <Composition of Coating Liquid for Forming Easy Adhesion Layer>

Polyolefin resin water dispersion liquid . . . 5.2% by mass (binder: “CHEMIPEARL S75N”, manufactured by MITSUI CHEMICALS, INC., 24% of solid matter content)

Polyoxyalkylene alkyl ether . . . 7.8% by mass (“NAROACTY CL95”, manufactured by Sanyo Chemical Industries, Ltd., 1% by mass of solid matter content)

Oxazoline compound . . . 0.8% by mass (“EPOCROS WS-700”, manufactured by NIPPON SHOKUBAI CO., LTD., 25% by mass of solid matter content)

Silica fine particle water dispersion . . . 2.9% by mass (“AEROSIL OX-50”, manufactured by Nippon Aerosil Co., Ltd., 10% by mass of solid matter content)

Distilled water . . . 83.3% by mass

After that, onto a side of the sample film opposite to the side thereof having the reflection layer and the easy adhesion layer formed thereon, the following (iii) undercoat layer, (iv) barrier layer, and (v) antifouling layer were applied by coating successively from the sample film side.

(iii) Undercoat Layer

Components with the following composition were mixed to prepare a coating liquid for forming an undercoat layer. The coating liquid was applied onto the sample film and dried at 180° C. for 1 (one) minute to form an undercoat layer (dried coating amount: about 0.1 g/m²).

### <Composition of Coating Liquid for Forming Undercoat Layer>

Polyester resin . . . 1.7% by mass (“VYLONAL MD-1200”, manufactured by TOYOBO CO., LTD., 17% by mass of solid matter content)

Polyester resin . . . 3.8% by mass (“PESRESIN A-520”, manufactured by TAKAMATSU OIL&FAT CO., LTD., 30% by mass of solid matter content)

Polyoxyalkylene alkyl ether . . . 1.5% by mass (“NAROACTY CL95”, manufactured by Sanyo Chemical Industries, Ltd., 1% by mass of solid matter content)

Carbodiimide compound . . . 1.3% by mass (“CARBODILITE V-02-L2”, manufactured by Nisshinbo Industries, Inc., 10% by mass of solid matter content)

Distilled water . . . 91.7% by mass

(iv) Barrier Layer

Subsequently, on the surface of thus formed undercoat layer, an 800 angstroms thick vacuum deposition film of silicon oxide was formed under the following vacuum deposition conditions. The film served as a barrier layer.

### <Vacuum Deposition Conditions>

Reactive gas mixing ratio (unit: slm): hexamethyl disiloxane/oxygen gas/helium=1/10/10

Vacuum degree inside vacuum chamber: 5.0×10⁻⁶ mbar

Vacuum degree inside deposition chamber: 6.0×10⁻² mbar

Electric power supplied to cooling and electrode drums: 20 kW

Film conveying speed: 80 m/minute

(v) Antifouling Layer

As described below, coating liquids for forming a first antifouling layer and a second antifouling layer were prepared. The coating liquid for forming the first antifouling layer and the coating liquid for forming the second antifouling layer were coated in this order on the barrier layer, so that an antifouling layer having a bi-layer structure was formed by coating.

<First Antifouling Layer>

—Preparation of Coating Liquid for Forming First Antifouling Layer—

Components with the following composition were mixed to prepare a coating liquid for forming the first antifouling layer.

### <Composition of Coating Liquid>

CERANATE WSA1070 . . . 45.9 parts (manufactured by DIC Corp.)

Oxazoline compound . . . 7.7 parts (cross-linking agent: “EPOCROS WS-700”, manufactured by NIPPON SHOKUBAI CO., LTD., 25% by mass of solid matter content)

Polyoxyalkylene alkyl ether . . . 2.0 parts (“NAROACTY CL95”, manufactured by Sanyo Chemical Industries, Ltd., 1% by mass of solid matter content)

Pigment dispersion used for the reflection layer . . . 33.0 parts

Distilled water . . . 11.4 parts

—Formation of First Antifouling Layer—

The resulting coating liquid was applied on the barrier layer in a coated amount of binder of 3.0 g/m², and dried at 180° C. for 1 minute to form the first antifouling layer.

—Preparation of Coating Liquid for Forming Second Antifouling Layer—

Components with the following composition were mixed to prepare a coating liquid for forming the second antifouling layer.

### <Composition of Coating Liquid>

Fluoro binder . . . 45.9 parts (“OBBLIGATO”, manufactured by AGC COAT-TECH CO., LTD.)

Oxazoline compound . . . 7.7 parts (cross-linking agent: “EPOCROS WS-700”, manufactured by NIPPON SHOKUBAI CO., LTD., 25% by mass of solid matter content)

Polyoxyalkylene alkyl ether . . . 2.0 parts (“NAROACTY CL95”, manufactured by Sanyo Chemical Industries, Ltd., 1% by mass of solid matter content)

Pigment dispersion prepared for forming the reflection layer . . . 33.0 parts

Distilled water . . . 11.4 parts

—Formation of Second Antifouling Layer—

The resulting coating liquid for forming the second antifouling layer was applied on the first antifouling layer, which was formed on the barrier layer, in a coated amount of binder of 2.0 g/m², and dried at 180° C. for 1 minute to form the second antifouling layer.

In this way, a back sheet that had the reflection layer and the easy adhesion layer on the one side of the polyester film, and the undercoat layer, the barrier layer, and the antifouling layers on the other side thereof was prepared.

—Evaluation of Back Sheet—

The back sheet including each layer (i) to (v) described above was subjected to a thermal treatment (120° C., 100% RH, 80 hours) and then evaluated in the same manner as above. As a result, it was found that the back sheet produced by using the polyester film of the Examples has good hydrolysis resistance and good voltage resistance compared to the back sheet produced by using the polyester film of the Comparative Examples.

[Construction of Solar Cell Module]

Each back sheet prepared as described above was adhered to a transparent filler to form the structure as in FIG. 1 in JP-A No. 2009-158952 to construct a solar cell module. At that time, adhesion was made such that the easy adhesion layer of the back sheet was in contact with the transparent filler in which solar cell devices were embedded.

TABLE 1

| | | | | Unstretched film | | | | | | | | | |
|---|---|---|---|---|---|---|---|---|---|---|---|---|---|
| | | | | | | Difference | | Surrounding | | | Half life | | |
| | Polyester resin | | | | | between | Mean | atmospheric | Smoothness | | of | | |
| | | | Amount | | | surface | tem- | temperature | | Pro- | rupture | | |
| | | | of | | | temperature | pera- | of | | trusions | elongation | | Overall |
| | | | terminal | | Thick- | and central | ture | pre-heating | | caused by | retention | Withstand | evaluation |
| | Resin | IV | COOH | Tg | ness | temperature | T1 | roll | Scratches | adhesion | ratio | voltage | (weather |
| | type | (dl/g) | (eq/t) | (° C.) | (mm) | (° C.) | (° C.) | (° C.) | (number) | (number) | (hr) | (V) | resistance) |
| Example 1 | PET | 0.78 | 27 | 75 | 2.52 | 3.5 | 75 | 30 | 3 | 2 | 2100 | 800 | B |
| Example 2 | PET | 0.78 | 27 | 75 | 3.50 | 5.2 | 75 | 30 | 3 | 3 | 2400 | 1150 | B |
| Example 3 | PET | 0.78 | 27 | 75 | 4.78 | 8 | 75 | 30 | 4 | 1 | 2500 | 1050 | B |
| Example 4 | PET | 0.78 | 27 | 75 | 3.5 | 0.3 | 75 | 30 | 3 | 3 | 2800 | 800 | B |
| Example 5 | PET | 0.78 | 27 | 75 | 3.5 | 5 | 75 | 30 | 2 | 3 | 3200 | 830 | B |
| Example 6 | PET | 0.78 | 27 | 75 | 3.5 | 8 | 75 | 30 | 2 | 3 | 3100 | 980 | B |
| Example 7 | PET | 0.78 | 27 | 75 | 3.5 | 14 | 75 | 30 | 4 | 1 | 2400 | 820 | B |
| Example 8 | PET | 0.78 | 27 | 75 | 3.5 | 3.8 | 56 | 30 | 4 | 2 | 3100 | 870 | B |
| Example 9 | PET | 0.78 | 27 | 75 | 3.5 | 4.2 | 74 | 30 | 3 | 2 | 2400 | 920 | B |
| Example 10 | PET | 0.78 | 27 | 75 | 3.5 | 6.5 | 95 | 30 | 3 | 4 | 2300 | 880 | B |
| Example 11 | PET | 0.78 | 27 | 75 | 3.5 | 3.5 | 75 | 55 | 2 | 0 | 3200 | 1000 | A |
| Example 12 | PET | 0.78 | 27 | 75 | 3.5 | 8.1 | 75 | 70 | 2 | 0 | 3500 | 1010 | A |
| Example 13 | PET | 0.78 | 27 | 75 | 3.5 | 5.4 | 75 | 88 | 1 | 1 | 3400 | 1120 | A |
| Example 14 | PET | 0.78 | 27 | 75 | 3.5 | 6.5 | 75 | 93 | 1 | 2 | 3300 | 1300 | A |
| Example 15 | PET | 0.62 | 27 | 75 | 3.5 | 7.3 | 75 | 30 | 2 | 2 | 3200 | 1200 | A |
| Example 16 | PET | 0.83 | 27 | 75 | 3.5 | 6.5 | 75 | 30 | 2 | 2 | 3800 | 980 | A |
| Example 17 | PET | 0.89 | 27 | 75 | 3.5 | 6.4 | 75 | 30 | 2 | 2 | 4000 | 1210 | A |
| Example 18 | PET | 0.78 | 5 | 75 | 3.5 | 5.2 | 75 | 30 | 2 | 2 | 4200 | 1250 | A |
| Example 19 | PET | 0.78 | 10 | 75 | 3.5 | 6.2 | 75 | 30 | 2 | 0 | 3500 | 1200 | A |
| Example 20 | PET | 0.78 | 25 | 75 | 3.5 | 4.2 | 75 | 30 | 2 | 0 | 3000 | 1050 | A |
| Comparative | PET | 0.78 | 27 | 75 | 2.38 | 1.2 | 75 | 30 | 2 | 3 | 2800 | 680 | C |
| Example 1 | | | | | | | | | | | | | |
| Comparative | PET | 0.78 | 27 | 75 | 5.10 | 10 | 75 | 30 | 7 | 2 | 2300 | 630 | C |
| Example 2 | | | | | | | | | | | | | |
| Comparative | PET | 0.78 | 27 | 75 | 3.5 | 0.2 | 75 | 30 | 3 | 5 | 1800 | 500 | C |
| Example 3 | | | | | | | | | | | | | |
| Comparative | PET | 0.78 | 27 | 75 | 3.5 | 15 | 75 | 30 | 8 | 1 | 2500 | 690 | C |
| Example 4 | | | | | | | | | | | | | |
| Comparative | PET | 0.78 | 27 | 75 | 3.5 | 5.2 | 54 | 30 | 6 | 1 | 2800 | 560 | C |
| Example 5 | | | | | | | | | | | | | |
| Comparative | PET | 0.78 | 27 | 75 | 3.5 | 5.4 | 97 | 30 | 2 | 8 | 1500 | 680 | C |
| Example 6 | | | | | | | | | | | | | |

It is found from the results listed in Table 1 that, when compared to the Comparative Examples, the polyester film obtained in each Example suppresses an occurrence of scratches during production or protrusions caused by adhesion, and thus has excellent surface smoothness, and has excellent hydrolysis resistance and voltage resistance.

This means that a polyester film for a solar cell in which the polyester film of the Examples is applied has excellent weather resistance, and that a solar cell module for power generation provided with the polyester film for a solar cell can provide stable electric power generation performance during a long period of time.

All publications, patent applications, and technical standards mentioned in this specification are herein incorporated by reference to the same extent as if each individual publication, patent application, or technical standard was specifically and individually indicated to be incorporated by reference.

### INDUSTRIAL APPLICABILITY

The polyester film of the invention is preferably used for the application of a back sheet (a sheet disposed on a side opposite to the sunlight incidence side with respect to a solar cell device; a so-called back sheet) for constituting a solar cell module, for example.

What is claimed is:

1. A method for producing a polyester film, the method comprising:
an unstretched film formation step of forming an unstretched polyester film having a thickness of from 2.5 mm to 5.0 mm by melt-extruding a polyester resin using an extruder, and cooling the polyester resin; and
a stretching step of stretching the formed unstretched polyester film in at least one direction after heating the formed unstretched polyester film so as to have a mean temperature T1 (° C.), a surface temperature, and a central temperature, wherein the mean temperature T1 (° C.) satisfies a relationship represented by the following formula (1), and the surface temperature is higher than the central temperature by from 0.3° C. to less than 15° C.
Tg−20° C.<T1<Tg+25° C. formula (1)
wherein in the formula (1), Tg represents a glass transition temperature (° C.) of the unstretched polyester film.

2. The method for producing a polyester film according to claim 1, wherein the stretching step is performed by, after heating the unstretched polyester film using a pre-heating roll, stretching the unstretched polyester film with a stretching roll while heating the film with a near infrared heater or a far infrared heater, and each of a surface temperature and a surrounding atmospheric temperature of the pre-heating roll is a temperature T2 (° C.) which satisfies a relationship represented by the following formula (2)
Tg−25° C.<T2<Tg+40° C. formula (2)
wherein in the formula (2), Tg represents the glass transition temperature (° C.) of the unstretched polyester film.

3. The method for producing a polyester film according to claim 1, wherein an intrinsic viscosity of the polyester resin is in a range of from 0.6 dl/g to 0.9 dl/g.

4. The method for producing a polyester film according to claim 1, wherein the polyester resin has a terminal COOH amount of from 5 eq/t to 25 eq/t.

5. The method for producing a polyester film according to claim 1, wherein the unstretched polyester film is stretched in a transfer direction in the stretching step.

6. A polyester film obtained by the method for producing a polyester film according to claim 1.

7. A back sheet for a solar cell, comprising the polyester film according to claim 6.

8. A solar cell module comprising the polyester film according to claim 6.

9. The method for producing a polyester film according to claim 2, wherein an intrinsic viscosity of the polyester resin is in a range of from 0.6 dl/g to 0.9 dl/g.

10. The method for producing a polyester film according to claim 2, wherein the polyester resin has a terminal COOH amount of from 5 eq/t to 25 eq/t.

11. The method for producing a polyester film according to claim 2, wherein the unstretched polyester film is stretched in a transfer direction in the stretching step.

12. A polyester film obtained by the method for producing a polyester film according to claim 2.

13. A back sheet for a solar cell, comprising the polyester film according to claim 12.

14. A solar cell module comprising the polyester film according to claim 12.
